(19) United States
(12) Patent Application Publication
(10) Pub. No.: US 2010/0002895 A1
(43) Pub. Date: Jan. 7, 2010

(54) CONDENSER MICROPHONE AND MEMS DEVICE

(75) Inventors: Hidenori NOTAKE, Osaka (JP); Tohru YAMAOKA, Niigata (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/539,892

(22) Filed: Aug. 12, 2009

Related U.S. Application Data
(63) Continuation of application No. PCT/JP2009/000002, filed on Jan. 5, 2009.

(30) Foreign Application Priority Data
Feb. 14, 2008 (JP) 2008-033408

(51) Int. Cl. H04R 11/04; H01L 29/84

(52) U.S. Cl. 381/174; 257/416; 257/E29.324

(57) ABSTRACT

An air gap is formed between a first film having a first electrode film and a second film having a second electrode film. The first film has a stopper protruding toward the second film, and a recess communicating with the air gap is provided in the center of the stopper.

This is a continuation of Application PCT/JP2009/000002, filed on Jan. 5, 2009.

### BACKGROUND OF THE INVENTION

The present invention relates to a microelectromechanical systems (MEMS) device such as a condenser microphone having a vibrating electrode and a fixed electrode.

In recent years, capacitive vibration sensors utilizing MEMS technology, as those disclosed in Patent Documents 1 and 2, have been proposed. The capacitive vibration sensors disclosed in Patent Documents 1 and 2 have a feature that a fixed electrode and a vibrating electrode are opposed to each other with an air gap (space) therebetween on a substrate and the fixed electrode has a stopper (protrusion). The stopper is provided for preventing the fixed electrode and the vibrating electrode from coming within a given distance of each other. Specifically, if condensation occurs in the air gap or a foreign matter such as water enters the air gap, the opposed fixed electrode and vibrating electrode may come into contact with each other via such a matter in some cases. In other cases, the opposed fixed electrode and vibrating electrode may be adsorbed to each other under electrostatic attraction. Such a state of the two opposed electrodes being in contact with each other is called sticking, and the above stopper has a role of preventing occurrence of sticking. In other words, with the stopper of the fixed electrode, the contact area between the two electrodes can be reduced, whereby sticking over the entire electrodes can be prevented.

Conventionally, organic high polymers such as a fluorinated ethylene propylene (FEP) material have been used as an electret that is a dielectric having permanent electric polarization and applied to devices such as an electret condenser microphone. However, the organic high polymers such as the FEP material, which are poor in heat resistance, have a problem of finding difficulty in application to elements for reflow mounted on a substrate (elements resistant to a soldering reflow temperature during mounting onto a substrate). Also, there have been requests for electrets thinner, smaller in size, and higher in performance. In view of the above, Patent Documents 3 and 4 propose electret-type silicon microphones using a silicon oxide film as an electret. In the microphones disclosed in Patent Documents 3 and 4, also, a first electrode functioning as the fixed electrode and a second electrode functioning as the vibrating electrode are opposed to each other with an air gap therebetween, and the first electrode has a stopper so that the opposed first and second electrodes are prevented from coming within a given distance of each other.
Patent Document 1: Japanese Laid-Open Patent Publication No. 2006-157863
Patent Document 2: Japanese Laid-Open Patent Publication No. 2007-267049
Patent Document 3: Japanese Laid-Open Patent Publication No. 2005-191208
Patent Document 4: Japanese Laid-Open Patent Publication No. 2006-074102

### SUMMARY OF THE INVENTION

However, the conventional stopper structures disclosed in Patent Documents 1 to 4 have a problem as follows. To ensure protection against sticking, it is required to increase the number of stoppers. An increased number of stoppers however may cause sticking between the stoppers and the electrode opposed to the stoppers. This phenomenon of causing sticking with the stoppers occurs in a situation that the surface tension of a foreign matter such as water becomes great compared with the restoring force acting to allow the two electrodes with a reduced distance therebetween to keep a given distance from each other. Such a situation is more likely to arise as the number of stoppers is greater. Hence, sticking is likely to occur as the number of stoppers increases.

An object of the present invention is to provide an excellent MEMS device in which the anti-sticking performance can be kept good without the necessity of changing the stopper size even when the number of stoppers is increased.

To attain the object described above, the condenser microphone of the present invention includes: a first film having a first electrode film; a second film having a second electrode film; and an air gap formed between the first film and the second film, wherein the first film has a stopper protruding toward the second film, and a recess communicating with the air gap is provided in the center of the stopper.

According to the condenser microphone of the present invention, a recess is provided in the center of each stopper of the first film having the first electrode film. Hence, the contact area between the stopper and the second film can be reduced even when the first film and the second film come close to each other. Accordingly, a high-performance condenser microphone good in sticking resistance can be implemented without the necessity of changing the stopper size even when the number of stoppers is increased.

In the condenser microphone of the present invention, preferably, the first electrode film is also formed inside the stopper. With this configuration, the stopper structure is in a mechanically low stress state, and hence problems such as that of the stopper structure itself being broken are less likely to occur.

In the condenser microphone of the present invention, preferably, the first electrode film is also formed in a portion of a rim of the stopper adjacent to the recess. With this configuration, the stopper structure is in a mechanically low stress state, and hence problems such as that of the stopper structure itself being broken are less likely to occur.

In the condenser microphone of the present invention, preferably, the bottom surface of the recess is flush with a surface of the first film facing the second film other than a portion of the stopper. With this configuration, the stopper and the recess can be formed with good size controllability by lithography.

In the condenser microphone of the present invention, preferably, the bottom surface of the recess is not flush with a surface of the first film facing the second film other than a portion of the stopper. With this configuration, a smaller protrusion (step) can be provided in the stopper compared with the case that the surfaces are flush with each other.

In the condenser microphone of the present invention, preferably, the first film further has a silicon nitride film covering a surface of the first electrode film facing the second film. With this configuration, the restoring force of the first film can be improved with the silicon nitride film that is strong in tensile stress.

In the condenser microphone of the present invention, preferably, the second film further has a silicon oxide film and a silicon nitride film covering the silicon oxide film.

This configuration permits the silicon oxide film to function as an electret film, and also can prevent charge stored in the silicon oxide film from escaping. In addition, the restoring force of the second film can be improved with the silicon nitride film that is strong in tensile stress.

In the condenser microphone of the present invention, preferably, the first electrode film is made of polysilicon. With this configuration, the first electrode film excellent in heat resistance and step coverage can be obtained while being evaded from metal contamination.

In the condenser microphone of the present invention, preferably, the second electrode film is made of polysilicon. With this configuration, the second electrode film excellent in heat resistance and step coverage can be obtained while being evaded from metal contamination.

The MEMS device of the present invention includes: a first film having a first electrode film; a second film having a second electrode film; and an air gap formed between the first film and the second film, wherein the first film has a stopper protruding toward the second film, and a recess communicating with the air gap is provided in the center of the stopper.

According to the MEMS device of the present invention, a recess is provided in the center of each stopper of the first film having the first electrode film. Hence, the contact area between the stopper and the second film can be reduced even when the first film and the second film come close to each other. Accordingly, a high-performance MEMS device good in sticking resistance can be implemented without the necessity of changing the stopper size even when the number of stoppers is increased.

According to the present invention, a high-performance MEMS device good in sticking resistance can be implemented without the necessity of changing the stopper size even when the number of stoppers is increased. Also, with good sticking resistance, the moisture resistance and condensation resistance of the MEMS device can be improved.

Also, according to the present invention, in formation of the air gap structure having a thickness of the order of several μm between the first film and the second film by wet etching, the contact area between the opposed films can be reduced even when the opposed films with the air gap therebetween are about to contact each other via a medium such as water and isopropyl alcohol (IPA). In other words, according to the present invention, a MEMS device capable of exerting strong sticking resistance even during fabrication can be implemented.

### BRIEF DESCRIPTION OF THE DRAWINGS

FIG. 1(a) is a cross-sectional view of a condenser microphone of Embodiment 1 of the present invention, FIG. 1(b) is a plan view of an acoustic hole of the condenser microphone of Embodiment 1, and FIG. 1(c) is a plan view of a stopper of the condenser microphone of Embodiment 1.

FIG. 2(a) is an enlarged cross-sectional view showing a preferred stopper structure for the condenser microphone of Embodiment 1 of the present invention, and FIGS. 2(b) and 2(c) are enlarged cross-sectional views showing other variations of the stopper structure for the condenser microphone of Embodiment 1.

FIGS. 3(a) and 3(b) are cross-sectional views showing process steps of a fabrication method for the condenser microphone of Embodiment 1 of the present invention.

FIGS. 4(a) and 4(b) are cross-sectional views showing process steps of the fabrication method for the condenser microphone of Embodiment 1 of the present invention.

FIGS. 5(a) and 5(b) are cross-sectional views showing process steps of the fabrication method for the condenser microphone of Embodiment 1 of the present invention.

FIGS. 6(a) and 6(b) are cross-sectional views showing process steps of the fabrication method for the condenser microphone of Embodiment 1 of the present invention.

FIGS. 7(a) and 7(b) are cross-sectional views showing process steps of the fabrication method for the condenser microphone of Embodiment 1 of the present invention.

FIGS. 8(a) and 8(b) are cross-sectional views showing process steps of the fabrication method for the condenser microphone of Embodiment 1 of the present invention.

FIG. 9 is a plan view of a pit for stopper formation formed in the fabrication method for the condenser microphone of Embodiment 1 of the present invention.

FIG. 10(a) is a cross-sectional view of a condenser microphone of Embodiment 2 of the present invention, FIG. 10(b) is a plan view of an acoustic hole of the condenser microphone of Embodiment 2, and FIG. 10(c) is a plan view of a stopper of the condenser microphone of Embodiment 2.

FIGS. 11(a) and 11(b) are cross-sectional views showing process steps of a fabrication method for the condenser microphone of Embodiment 2 of the present invention.

FIGS. 12(a) and 12(b) are cross-sectional views showing process steps of the fabrication method for the condenser microphone of Embodiment 2 of the present invention.

FIGS. 13(a) and 13(b) are cross-sectional views showing process steps of the fabrication method for the condenser microphone of Embodiment 2 of the present invention.

FIGS. 14(a) and 14(b) are cross-sectional views showing process steps of the fabrication method for the condenser microphone of Embodiment 2 of the present invention.

FIGS. 15(a) and 15(b) are cross-sectional views showing process steps of the fabrication method for the condenser microphone of Embodiment 2 of the present invention.

FIGS. 16(a) and 16(b) are cross-sectional views showing process steps of the fabrication method for the condenser microphone of Embodiment 2 of the present invention.

FIG. 17 is a plan view of a pit for stopper formation formed in the fabrication method for the condenser microphone of Embodiment 2 of the present invention.

FIG. 18(a) is a cross-sectional view of a condenser microphone of Embodiment 3 of the present invention, FIG. 18(b) is a plan view of an acoustic hole of the condenser microphone of Embodiment 3, and FIG. 18(c) is a plan view of a stopper of the condenser microphone of Embodiment 3.

FIGS. 19(a) and 19(b) are cross-sectional views showing process steps of a fabrication method for the condenser microphone of Embodiment 3 of the present invention.

FIGS. 20(a) and 20(b) are cross-sectional views showing process steps of the fabrication method for the condenser microphone of Embodiment 3 of the present invention.

FIGS. 21(a) and 21(b) are cross-sectional views showing process steps of the fabrication method for the condenser microphone of Embodiment 3 of the present invention.

FIGS. 22(a) and 22(b) are cross-sectional views showing process steps of the fabrication method for the condenser microphone of Embodiment 3 of the present invention.

FIGS. 23(a) and 23(b) are cross-sectional views showing process steps of the fabrication method for the condenser microphone of Embodiment 3 of the present invention.

FIGS. 24(a) and 24(b) are cross-sectional views showing process steps of the fabrication method for the condenser microphone of Embodiment 3 of the present invention.

FIG. 25 is a cross-sectional view showing a process step of the fabrication method for the condenser microphone of Embodiment 3 of the present invention.

FIG. 26 is a plan view of a pit for stopper formation (before formation of a sub-trench) formed in the fabrication method for the condenser microphone of Embodiment 3 of the present invention.

FIG. 27 is a plan view of a pit for stopper formation (after formation of a sub-trench) formed in the fabrication method for the condenser microphone of Embodiment 3 of the present invention.

### DETAILED DESCRIPTION OF THE INVENTION

### Embodiment 1

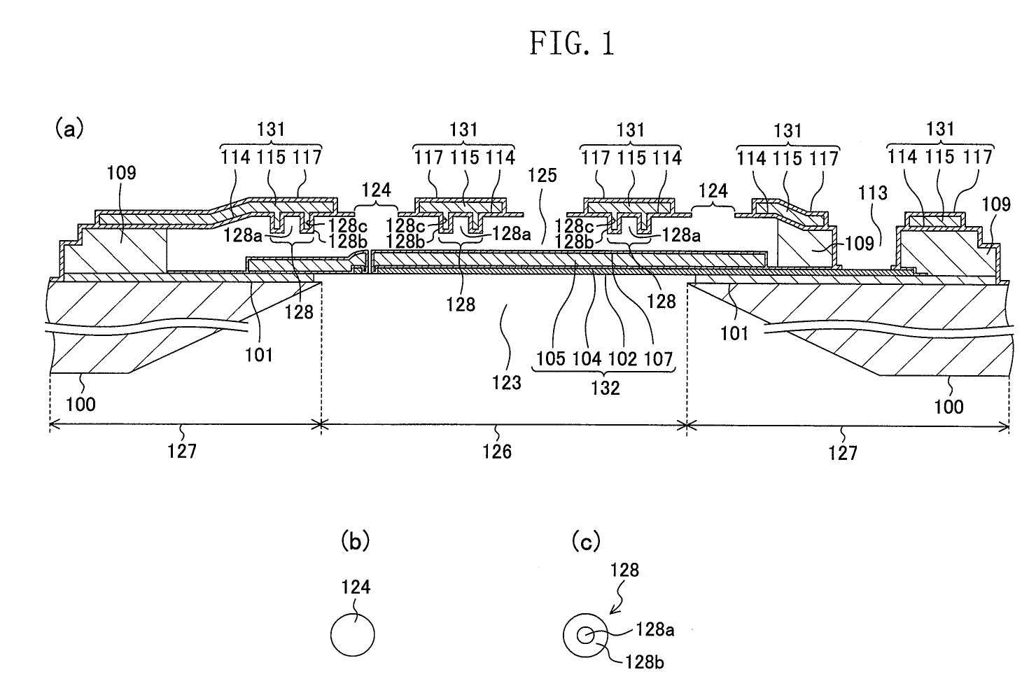

Hereinafter, a condenser microphone of Embodiment 1 of the present invention will be described with reference to FIGS. 1(a) to 1(c).

As shown in the cross-sectional view of FIG. 1(a), the condenser microphone of Embodiment 1 of the present invention includes a semiconductor substrate 100 having a substrate removed portion 123 in the center, or to state differently, a semiconductor substrate 100 having a membrane region 126 and a peripheral region 127 (part of the region outside the membrane region 126). As the semiconductor substrate 100, used is a silicon single crystal having a (100) principal plane and a specific resistance of 10 to 15 Ω·cm, for example. A protection oxide film (first silicon oxide film) 101 is formed on the peripheral region 127 of the semiconductor substrate 100. A multilayer film (second multilayer film) 132 made of a polysilicon film (first conductive polysilicon film) 102, a silicon nitride film (first silicon nitride film) 104, a silicon oxide film (second silicon oxide film) 105, and a silicon nitride film (second silicon nitride film) 107 is formed on the membrane region 126 of the semiconductor substrate 100 and the protection oxide film 101. The polysilicon film 102, serving as a second electrode (vibrating electrode), is formed under the silicon nitride film 104. The silicon nitride film 104 is formed to cover the bottom of the silicon oxide film 105, while the silicon nitride film 107 is formed to cover the top and sides of the silicon oxide film 105. The silicon oxide film 105, which stores charge, functions as an electret film.

Also, as shown in FIG. 1(a), a multilayer film (first multilayer film) 131 made of a silicon nitride film (third silicon nitride film) 114, a polysilicon film (second conductive polysilicon film) 115, and a silicon nitride film (fourth silicon nitride film) 117 is formed on the second multilayer film 132. Acoustic holes 124 as through holes are formed through the first multilayer film 131. The shape of each acoustic hole 124 in plan is shown in FIG. 1(b). The polysilicon film 115 serves as a first electrode (fixed electrode). The silicon nitride film 114 is formed to cover the bottom of the polysilicon film 115, while the silicon nitride film 117 is formed to cover the top and sides of the polysilicon film 115. Between the first multilayer film 131 and the second multilayer film 132, an air gap 125 exists, which is formed by etching away part of an atmospheric-pressure chemical vapor deposition (CVD) oxide film, for example, a boron-doped phospho-silicate glass (BPSG) film (third silicon oxide film) 109. The remainder of the BPSG film 109 left unetched serves as a support layer for supporting the first multilayer film 131. A second electrode pad opening 113 is formed through the BPSG film 109 to reach the polysilicon film 102 that is to be the second electrode (vibrating electrode).

A feature of Embodiment 1 is that the first multilayer film 131 has a plurality of stoppers 128 protruding toward the second multilayer film 132 and a recess 128a communicating with the air gap 125 is provided in the center of each stopper 128. The stoppers 128 have a height of about 1500 nm, for example, and a diameter of about 4 μm, for example. The diameter of the recess 128a is about 2 μm, for example, and the density of the stoppers 128 is about one/35000 μm² to one/180000 μm², for example. A rim 128b surrounding the recess 128a of each stopper 128 is made of a portion of the silicon nitride film 114 (part of the first multilayer film 131) formed to protrude toward the second multilayer film 132 and a portion of the polysilicon film 115 filling a groove 128c formed from the protrusion. In other words, the polysilicon film 115 is embedded in the rim of each stopper 128. The shape of the stopper 128 in plan is shown in FIG. 1(c).

In Embodiment 1, the bottom surface of the recess 128a of each stopper 128 is flush with the surface of the first multilayer film 131 (specifically, the silicon nitride film 114) facing the second multilayer film 132 other than the portions of the stoppers 128. Also, the polysilicon film 115 also exists in a portion of the rim 128b of each stopper 128 adjacent to the recess 128a.

In the condenser microphone of Embodiment 1, in which the recess 128a communicating with the air gap 125 is formed in the center of each stopper 128 of the first multilayer film 131, the contact area between the stopper 128 and the second multilayer film 132 can be reduced even when the first multilayer film 131 and the second multilayer film 132 come close to each other. Hence, even if a foreign matter including water enters the air gap 125, the surface tension of such a foreign matter will be small, and thus the sticking phenomenon can be reliably suppressed. Accordingly, a high-performance condenser microphone good in sticking resistance can be implemented without the necessity of changing the stopper size even when the number of stoppers is increased.

Also, in the condenser microphone of Embodiment 1, the inventive stopper structure described above can solve a problem that the first multilayer film 131 and the second multilayer film 132 may stick to each other due to the surface tension of an etchant, a cleaning solution, or the like. That is, a condenser microphone capable of exerting strong sticking resistance even during fabrication can be implemented.

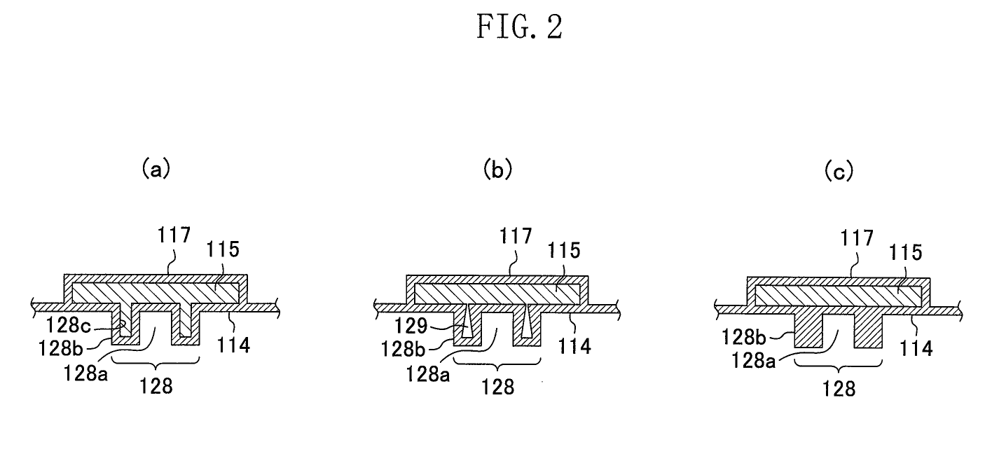

FIG. 2(a) is an enlarged cross-sectional view of the preferred stopper structure in this embodiment. That is, as shown in FIG. 2(a), it is preferred in this embodiment to ensure that the polysilicon film 115 is embedded in the rim 128b of the stopper 128.

FIGS. 2(b) and 2(c) are enlarged cross-sectional views showing other variations of the stopper structure in this embodiment. Specifically, in this embodiment, as shown in FIG. 2(b), a void 129 unfilled with the polysilicon film 115 due to overhanging of the silicon nitride film 114 may be formed inside the rim 128b of the stopper 128. Otherwise, as shown in FIG. 2(c), the rim 128b of the stopper 128 may be entirely made of the silicon nitride film 114; that is, the polysilicon film 115 may not be embedded in the rim 128b of the stopper 128.

In this embodiment, the reason why the structure of the rim 128b of the stopper 128 with the polysilicon film 115 embedded therein, or the structure shown in FIG. 2(a), is preferred to the structures shown in FIGS. 2(b) and 2(c) is as follows. The polysilicon film is low in stress compared with the silicon nitride film. Hence, the structure of the rim 128b of the stopper 128 being entirely made of the silicon nitride film 114, or the structure of the rim 128b of the stopper 128 having the void 129 unfilled with the polysilicon film 115, tends to be in a mechanically high stress state. In these structures, therefore, the stopper 128 itself may possibly be broken from the nature of the stopper 128, for example. In consideration of the above, as the stopper structure in this embodiment, the structure of the rim 128b of the stopper 128 with the polysilicon film 115 reliably embedded therein is preferred in the point that the effect of providing mechanically low stress is obtained.

Also, it is preferred that, as in this embodiment, the silicon nitride films 114 and 107 are formed on the bottom of the first multilayer film 131 (specifically, the surface of the polysilicon film 115 facing the second multilayer film 132) and the top of the second multilayer film 132 (specifically, the surface of the silicon oxide film 105 facing the first multilayer film 131), respectively. With this formation, the silicon nitride films, which are strong in tensile stress, can improve the restoring force (force acting to resume the original shape) of the multilayer films 131 and 132.

It is also preferred that, as in this embodiment, the top, sides, and bottom of the silicon oxide film 105 functioning as the electret film in the second multilayer film 132 are covered with the silicon nitride films 104 and 107. With this, charge stored in the silicon oxide film 105 is prevented from escaping therefrom.

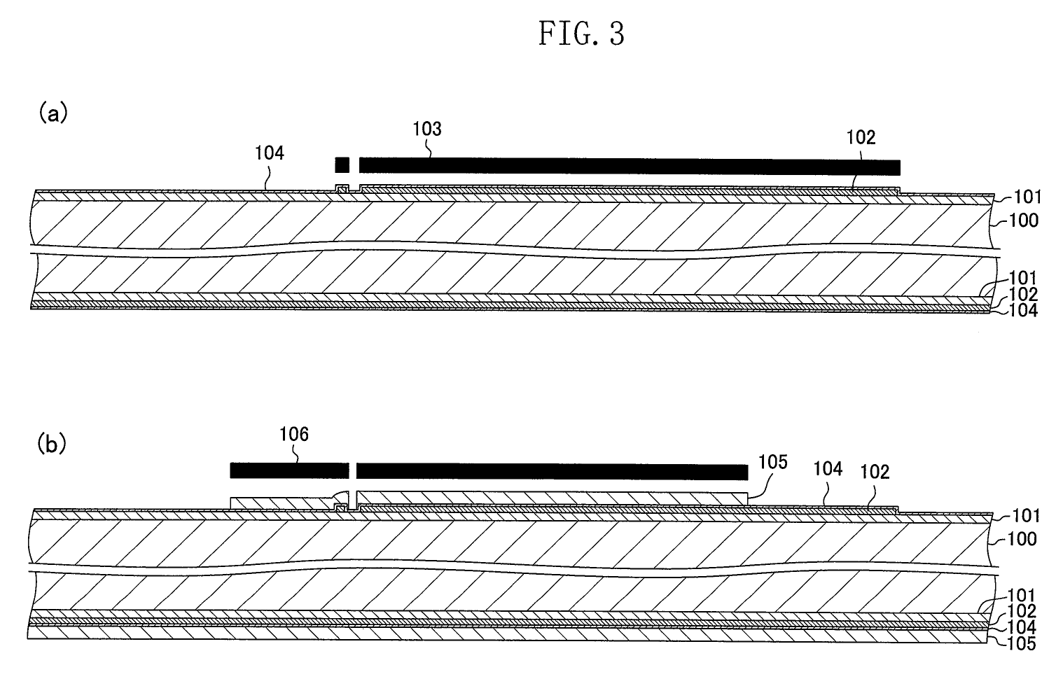

Next, a fabrication method for the condenser microphone of Embodiment 1 of the present invention will be described with reference to the cross-sectional views of FIGS. 3(a), 3(b), 4(a), 4(b), 5(a), 5(b), 6(a), 6(b), 7(a), 7(b), 8(a), and 8(b) showing process steps of the fabrication method. Note that description of resist film removal steps is omitted because the steps follow normal processing. Also, it is needles to mention that the numeric values of the thicknesses and the like, the materials of the film species and the like, the methods such as the etching method, and the like in the following description are all presented for mere illustration.

First, as shown in FIG. 3(a), the protection oxide film (first silicon oxide film) 101 having a thickness of 1000 nm, for example, is formed on the p-type semiconductor substrate 100 made of a silicon single crystal having a (100) principal plane and a specific resistance of 10 to 15 Ω·cm. Thereafter, the p-type polysilicon film (first conductive polysilicon film) 102 that is to be the second electrode (vibrating electrode) is grown on the protection oxide film 101 to a thickness of 300 nm by low-pressure CVD. The polysilicon film 102 is doped with phosphorus in a concentration of 2×10²⁰ to 3×10²⁰ atoms/cm³, for example. A resist pattern (not shown) is then formed using a mask 103 for photolithography, and using the resist pattern as a mask, the polysilicon film 102 is formed into a predetermined shape by dry etching, for example. The resist pattern is then peeled off. The silicon nitride film (first silicon nitride film) 104, for example, is then grown on the protection oxide film 101 and the polysilicon film 102 to a thickness of 100 nm as an insulating film. Note that at this time, the protection oxide film 101, the polysilicon film 102, and the silicon nitride film 104 are also formed on the back of the semiconductor substrate 100.

As shown in FIG. 3(b), the tetraethylorthosilicate (TEOS) (second silicon oxide film) 105 is grown on the silicon nitride film 104 to a thickness of 1000 nm by low-pressure CVD. At this time, the TEOS film 105 is also formed on the back of the semiconductor substrate 100. A resist pattern (not shown) is then formed using a mask 106 for photolithography, and using the resist pattern as a mask, the TEOS film 105 is formed into a predetermined shape by dry etching, for example. The resist pattern is then peeled off.

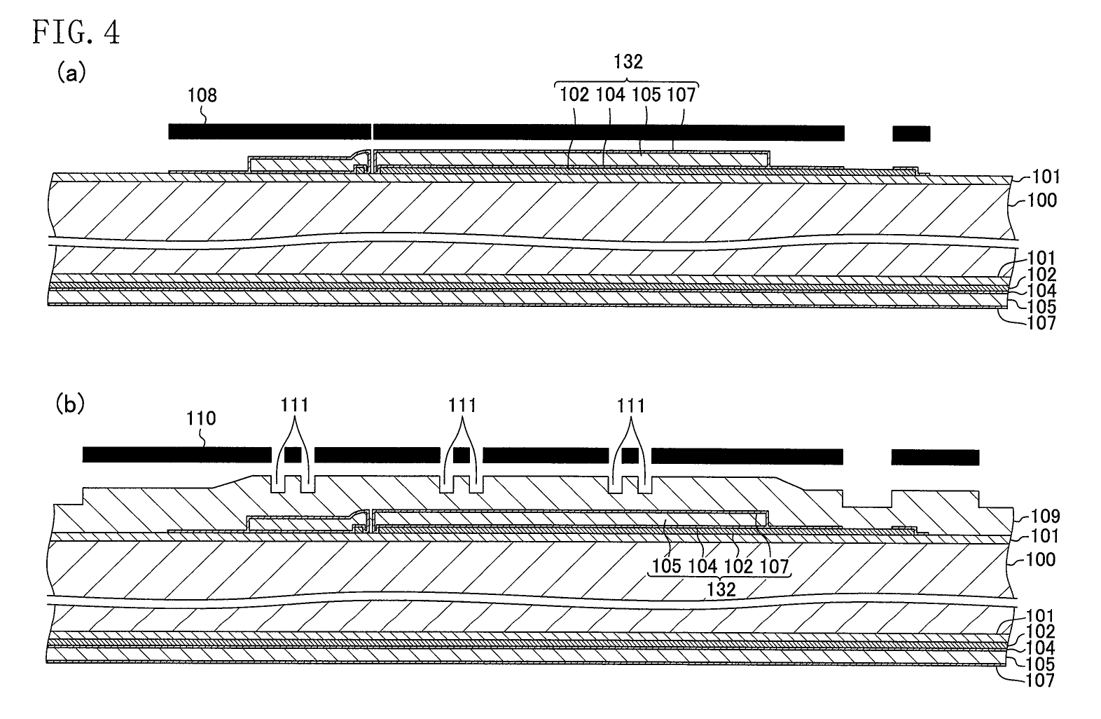

As shown in FIG. 4(a), the silicon nitride film (second silicon nitride film) 107, for example, is then grown on the TEOS film 105 to a thickness of 100 nm as an insulating film. At this time, the silicon nitride film 107 is also formed on the back of the semiconductor substrate 100. A resist pattern (not shown) is then formed using a mask 108 for photolithography, and using the resist pattern as a mask, the silicon nitride film 107 is formed into a predetermined shape by dry etching, for example. In this way, the second multilayer film 132 made of the polysilicon film 102, the silicon nitride film 104, the silicon oxide film 105, and the silicon nitride film 107 is formed. Note that at this etching, a portion of the silicon nitride film 107 in a region for formation of a pad for the second electrode is removed. The resist pattern is then peeled off.

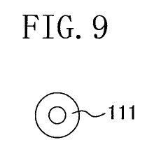

As shown in FIG. 4(b), an atmospheric-pressure CVD oxide film, for example, the BPSG film (third silicon oxide film) 109, is grown on the silicon nitride film 107 to a thickness of 3000 nm. In a later process step, part of the BPSG film 109 is etched away to form the air gap. That is, the BPSG film 109 serves as a sacrificial layer. A resist pattern (not shown) is then formed using a mask 110 for photolithography, and using the resist pattern as a mask, the BPSG film 109 is dry-etched, for example, to form pits 111 for stopper formation. The depth of the pits 111 is 1500 nm, for example. At this time, a portion of the BPSG film 109 in the second electrode pad formation region is removed by a predetermined thickness. The resist pattern is then peeled off. The shape of the pit 111 in plan is shown in FIG. 9. As shown in FIG. 9, the pit 111 is formed to have a roughly circular protrusion of the BPSG film 109 left in the center by etching a portion of the BPSG film 109 surrounding the protrusion in a roughly ring shape.

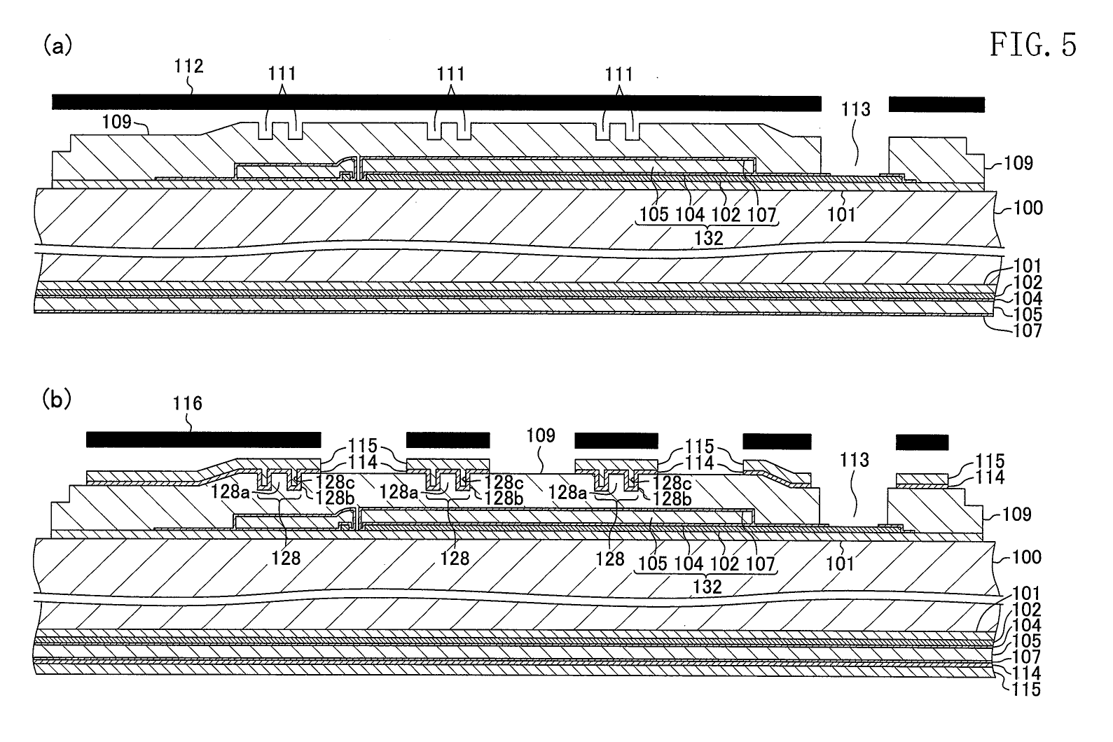

As shown in FIG. 5(a), a resist pattern (not shown) is formed using a mask 112 for photolithography, and using the resist pattern as a mask, the BPSG film 109 is dry-etched, for example, to form the second electrode pad opening 113 reaching the polysilicon film 102 that is to be the second electrode (vibrating electrode). The resist pattern is then peeled off.

As shown in FIG. 5(b), as an insulating film, the silicon nitride film (third silicon nitride film) 114, for example, is formed on the entire surface of the BPSG film 109 including the insides of the pits 111 and the inside of the second electrode pad opening 113 to a thickness of 100 nm. Subsequently, the p-type polysilicon film (second conductive polysilicon film) 115 that is to be the first electrode (fixed electrode) is grown on the silicon nitride film 114 to a thickness of 1000 nm by low-pressure CVD. The polysilicon film 115 is doped with phosphorus in a concentration of 1×10²⁰ to 2×10²⁰ atoms/cm³, for example. At this time, the silicon nitride film 114 and the polysilicon film 115 are also formed on the back of the semiconductor substrate 100. Thereafter, a resist pattern (not shown) is formed using a mask 116 for photolithography, and the silicon nitride film 114 and the polysilicon film 115 are formed into a predetermined shape by dry etching, for example. In this way, the stoppers 128 according to the present invention shown in FIGS. 1(a) and 1(c) are formed. The resist pattern is then peeled off.

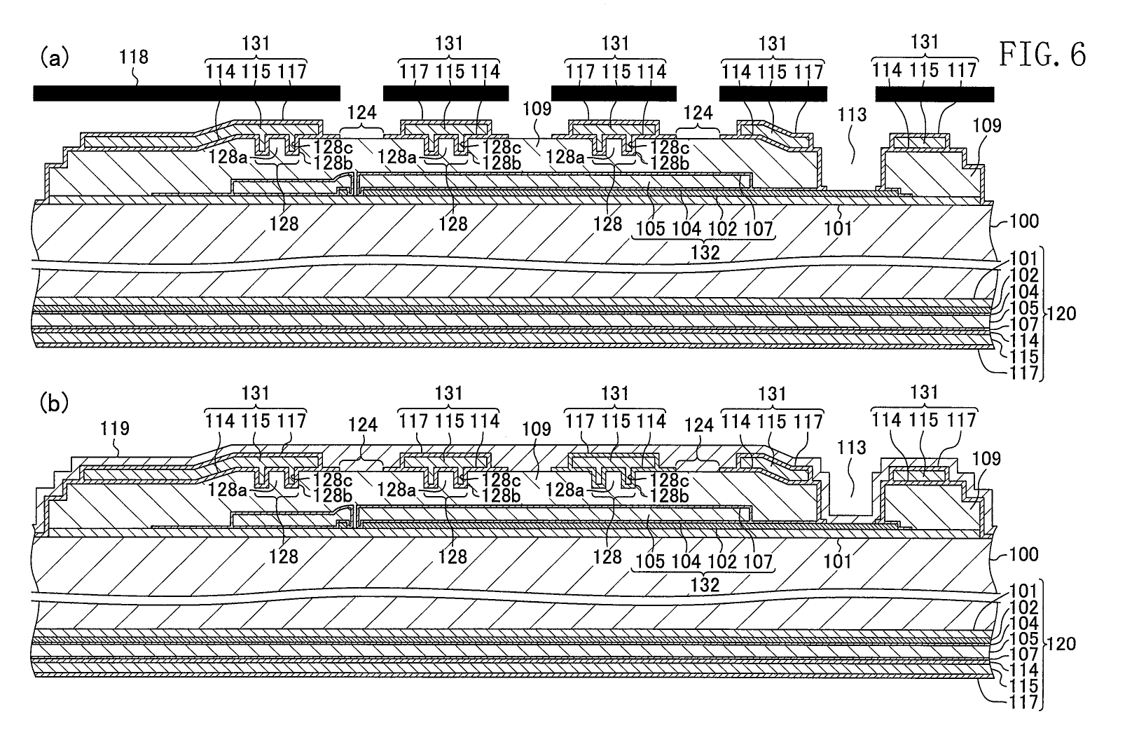

As shown in FIG. 6(a), the silicon nitride film (fourth silicon nitride film) 117 is formed on the entire surface of the BPSG film 109 including the top of the polysilicon film 115 and the inside of the second electrode pad opening 113 to a thickness of 150 nm. At this time, the silicon nitride film 117 is also formed on the back of the semiconductor substrate 100. Hereinafter, the multilayer film on the back of the substrate including the silicon nitride film 117 is called a substrate back multilayer film 120. Thereafter, a resist pattern (not shown) is formed using a mask 118 for photolithography, and using the resist pattern as a mask, the silicon nitride film 117 is formed into a predetermined shape by dry etching, for example. In this way, the first multilayer film 131 made of the silicon nitride film 114, the polysilicon film 115, and the silicon nitride film 117 is formed. The resist pattern is then peeled off.

As shown in FIG. 6(b), a fluorosilicate glass (FSG) film (fourth silicon oxide film) 119 functioning as a protection film is grown on the entire surface of the BPSG film 109 including the top of the silicon nitride film 117 and the inside of the second electrode pad opening 113 to a thickness of 500 nm.

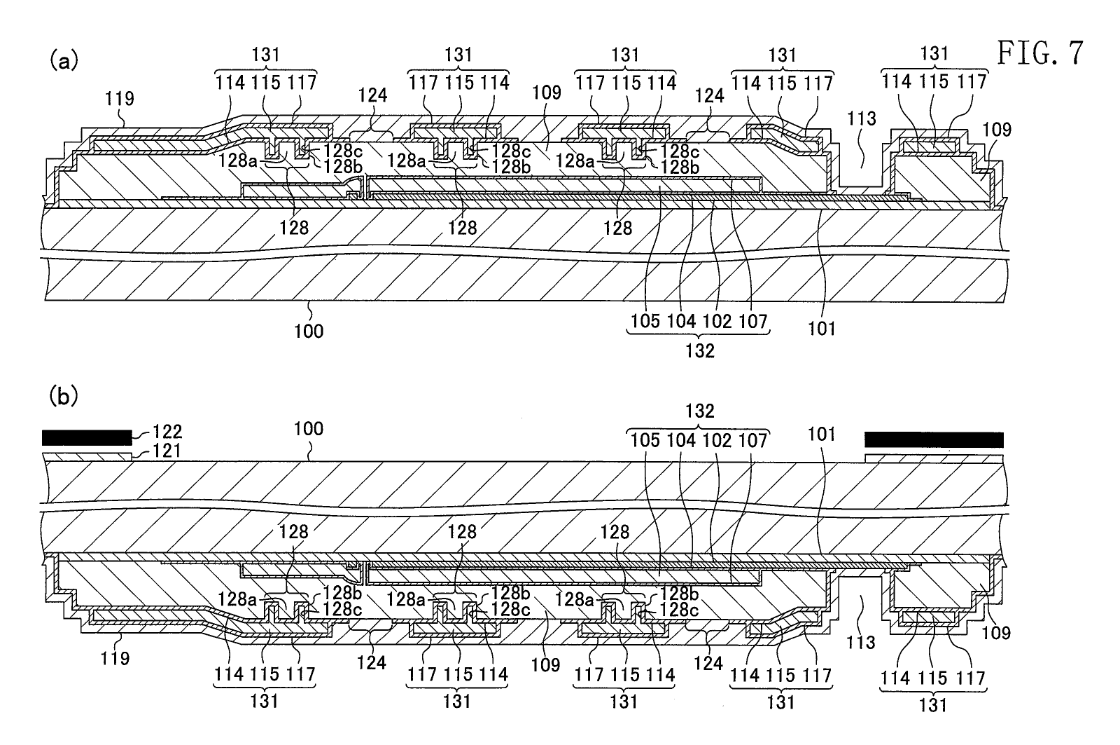

As shown in FIG. 7(a), the substrate back multilayer film 120 is peeled off using back-grinding equipment, for example, to expose the back of the semiconductor substrate 100.

As shown in FIG. 7(b), a silicon oxide film (fifth silicon oxide film) 121 functioning as a protection film is grown on the back of the semiconductor substrate 100 to a thickness of 500 nm. Thereafter, a resist pattern (not shown) is formed using a mask 122 for photolithography, and using the resist pattern as a mask, the silicon oxide film 121 is formed into a predetermined shape by dry etching, for example.

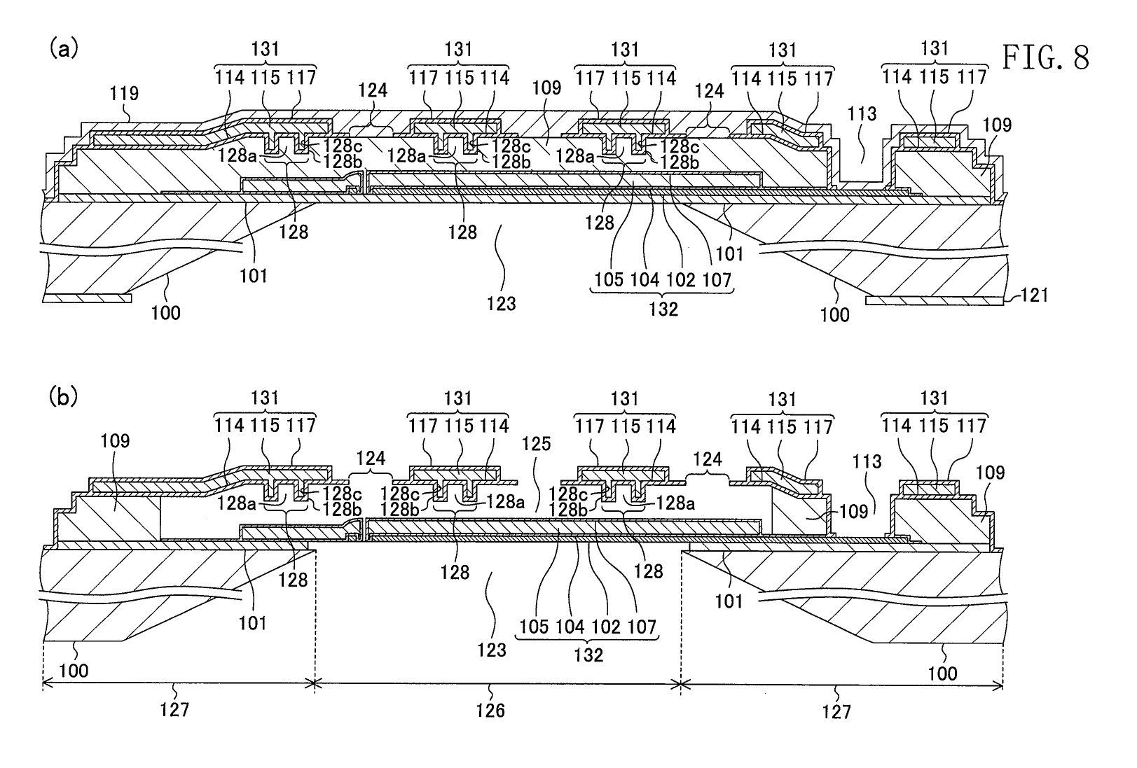

As shown in FIG. 8(a), using the silicon oxide film 121 as the protection film, the semiconductor substrate 100 is subjected to anisotropy etching with a liquid agent such as tetramethyl ammonium hydroxide (TMAH), to form a substrate removed portion 123 extending through the center of the semiconductor substrate 100.

As shown in FIG. 8(b), the semiconductor substrate 100 (chip) with the multilayer films 131 and 132 formed thereon is immersed in an undiluted HF solution, to remove the FSG film 119 functioning as the protection film, the silicon oxide film 121, the BPSG film 109 (predetermined portion), and the protection oxide film 101 (predetermined portion) by wet etching. In this way, the air gap 125 communicating with the acoustic holes 124 is formed between the first multilayer film 131 and the second multilayer film 132.

Finally, charge is applied to the silicon oxide film 105 as the electret film covered with the silicon nitride films 104 and 107 to turn the silicon oxide film 105 into an electret, to thereby complete the condenser microphone.

### Embodiment 2

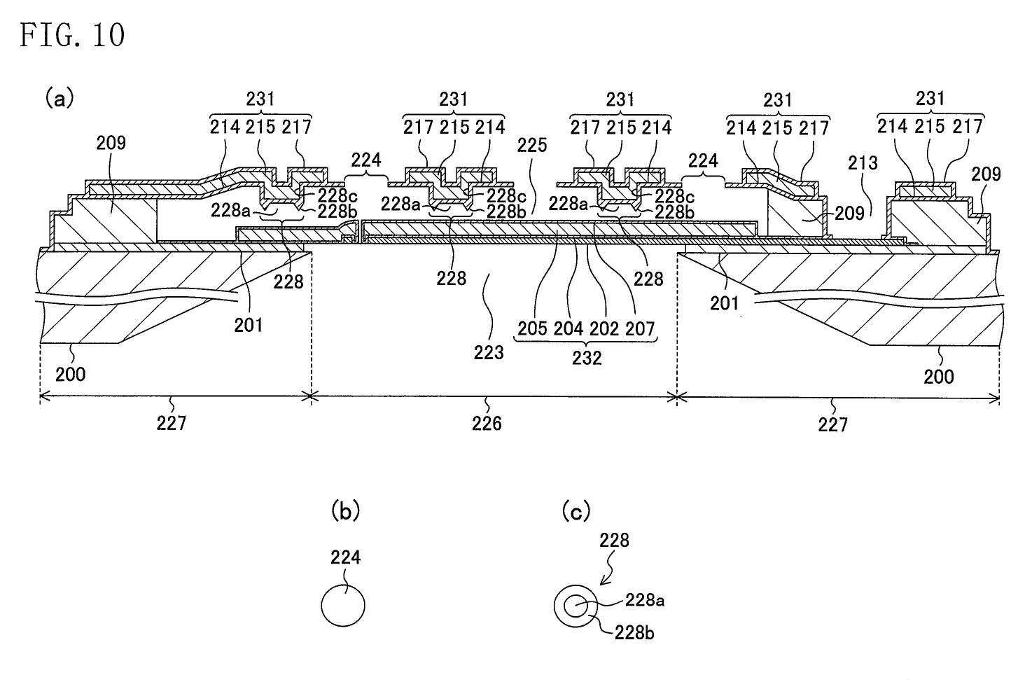

Hereinafter, a condenser microphone of Embodiment 2 of the present invention will be described with reference to FIGS. 10(a) to 10(c).

As shown in the cross-sectional view of FIG. 10(a), the condenser microphone of Embodiment 2 includes a semiconductor substrate 200 having a substrate removed portion 223 in the center, or to state differently, a semiconductor substrate 200 having a membrane region 226 and a peripheral region 227 (part of the region outside the membrane region 226). As the semiconductor substrate 200, used is a silicon single crystal having a (100) principal plane and a specific resistance of 10 to 15 Ω·cm, for example. A protection oxide film (first silicon oxide film) 201 is formed on the peripheral region 227 of the semiconductor substrate 100. A multilayer film (second multilayer film) 232 made of a polysilicon film (first conductive polysilicon film) 202, a silicon nitride film (first silicon nitride film) 204, a silicon oxide film (second silicon oxide film) 205, and a silicon nitride film (second silicon nitride film) 207 is formed on the membrane region 226 of the semiconductor substrate 200 and the protection oxide film 201. The polysilicon film 202, serving as a second electrode (vibrating electrode), is formed under the silicon nitride film 204. The silicon nitride film 204 is formed to cover the bottom of the silicon oxide film 205, while the silicon nitride film 207 is formed to cover the top and sides of the silicon oxide film 205. The silicon oxide film 205, which stores charge, functions as an electret film.

Also, as shown in FIG. 10(a), a multilayer film (first multilayer film) 231 made of a silicon nitride film (third silicon nitride film) 214, a polysilicon film (second conductive polysilicon film) 215, and a silicon nitride film (fourth silicon nitride film) 217 is formed on the second multilayer film 232. Acoustic holes 224 as through holes are formed through the first multilayer film 231. The shape of each acoustic hole 224 in plan is shown in FIG. 10(b). The polysilicon film 215 serves as a first electrode (fixed electrode). The silicon nitride film 214 is formed to cover the bottom of the polysilicon film 215, while the silicon nitride film 217 is formed to cover the top and sides of the polysilicon film 215. Between the first multilayer film 231 and the second multilayer film 232, an air gap 225 exists, which is formed by etching away part of an atmospheric-pressure CVD oxide film, for example, a BPSG film (third silicon oxide film) 209. The remainder of the BPSG film 209 left unetched serves as a support layer for supporting the first multilayer film 231. A second electrode pad opening 213 is formed through the BPSG film 209 to reach the polysilicon film 202 that is to be the second electrode (vibrating electrode).

A feature of Embodiment 2 is that the first multilayer film 231 has a plurality of stoppers 228 protruding toward the second multilayer film 232 and a recess 228a communicating with the air gap 225 is formed in the center of each stopper 228. The stoppers 228 have a height of about 1500 nm, for example, and a diameter of about 4 μm, for example. The diameter of the recess 228a (diameter of the bottom) is about 3 μm, for example, and the density of the stoppers 228 is about one/35000 μm² to one/180000 μm², for example. Specifically, each stopper 228 is made of a portion of the silicon nitride film 214 (part of the first multilayer film 231) formed to protrude toward the second multilayer film 232 and a portion of the polysilicon film 215 filling a groove 228c formed from the protrusion. Also, a rim 228b of each stopper 228 further protrudes toward the second multilayer film 232 with respect to the other portion by about 150 to 300 nm, to form the recess 228a surrounded by the rim 228b. The shape of the stopper 228 in plan is shown in FIG. 10(c).

Unlike Embodiment 1, the polysilicon film 215 is not embedded in a portion of the rim 228b of each stopper 228 adjacent to the recess 228a.

Also, in the stoppers 228 in Embodiment 2, unlike those in Embodiment 1, the bottom surface of the recess 228a of each stopper 228 is not flush with the surface of the first multilayer film 231 (specifically, the silicon nitride film 214) facing the second multilayer film 232 other than the portions of the stoppers 228. In other words, while the recess 128a of each stopper 128 is deep enough to reach the level of the surface of the first multilayer film 131 facing the second multilayer film 132 other than the portions of the stoppers 128 in Embodiment 1 as shown in FIG. 1(a), the recess 228a of each stopper 228 is not deep enough to reach the level of the surface of the first multilayer film 231 facing the second multilayer film 232 other than the portions of the stoppers 228 in Embodiment 2 as shown in FIG. 10(a). To state differently, the bottom of the recess 228a is located closer to the second multilayer film 232 than the surface of the first multilayer film 231 facing the second multilayer film 232 other than the portions of the stoppers 228 is. Hence, in the stoppers 228 in Embodiment 2, the polysilicon film 215 is embedded in a portion of each stopper 228 ranging from the surface of the first multilayer film 231 facing the second multilayer film 232 other than the portions of the stoppers 228 to the bottom of the recess 228a.

In the condenser microphone of Embodiment 2, in which the recess 228a communicating with the air gap 225 is formed in the center of each stopper 228 of the first multilayer film 231, the contact area between the stopper 228 and the second multilayer film 232 can be reduced even when the first multilayer film 231 and the second multilayer film 232 come close to each other. Hence, even if a foreign matter including water enters the air gap 225, the surface tension of such a foreign matter will be small, and thus the sticking phenomenon can be reliably suppressed. Accordingly, a high-performance condenser microphone good in sticking resistance can be implemented without the necessity of changing the stopper size even when the number of stoppers is increased.

Also, in the condenser microphone of Embodiment 2, the inventive stopper structure described above can solve a problem that the first multilayer film 231 and the second multilayer film 232 may stick to each other due to the surface tension of an etchant, a cleaning solution, or the like. That is, a condenser microphone capable of exerting strong sticking resistance even during fabrication can be implemented.

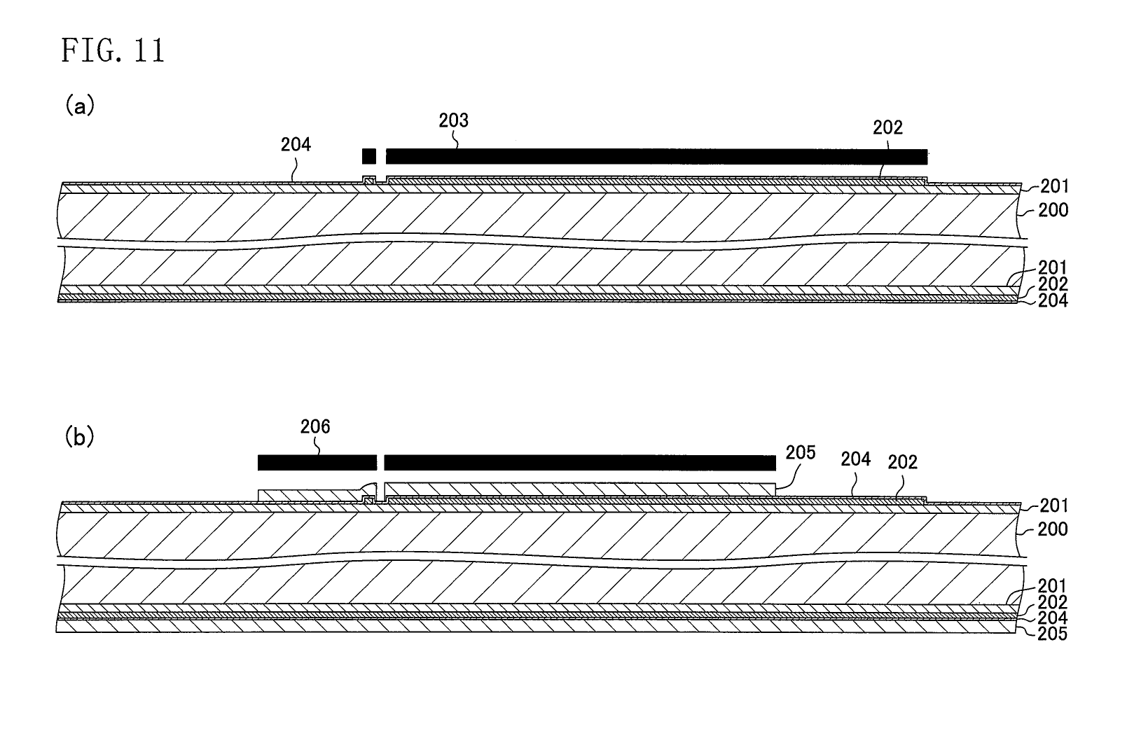

Next, a fabrication method for the condenser microphone of Embodiment 2 of the present invention will be described with reference to the cross-sectional views of FIGS. 11(a), 11(b), 12(a), 12(b), 13(a), 13(b), 14(a), 14(b), 15(a), 15(b), 16(a), and 16(b) showing process steps of the fabrication method. Note that description of resist film removal steps is omitted because the steps follow normal processing. Also, it is needless to mention that the numeric values of the thicknesses and the like, the materials of the film species and the like, the methods such as the etching method, and the like in the following description are all presented for mere illustration.

First, as shown in FIG. 11(a), the protection oxide film (first silicon oxide film) 201 having a thickness of 1000 nm, for example, is formed on the p-type semiconductor substrate 200 made of a silicon single crystal having a (100) principal plane and a specific resistance of 10 to 15 Ω·cm. Thereafter, the p-type polysilicon film (first conductive polysilicon film) 202 that is to be the second electrode (vibrating electrode) is grown on the protection oxide film 201 to a thickness of 300 nm by low-pressure CVD. The polysilicon film 202 is doped with phosphorus in a concentration of 2×10²⁰ to 3×10²⁰ atoms/cm³, for example. A resist pattern (not shown) is then formed using a mask 203 for photolithography, and using the resist pattern as a mask, the polysilicon film 202 is formed into a predetermined shape by dry etching, for example. The resist pattern is then peeled off. The silicon nitride film (first silicon nitride film) 204, for example, is then grown on the protection oxide film 201 and the polysilicon film 202 to a thickness of 100 μm as an insulating film. Note that at this time, the protection oxide film 201, the polysilicon film 202, and the silicon nitride film 204 are also formed on the back of the semiconductor substrate 200.

As shown in FIG. 11(b), the TEOS (second silicon oxide film) 205 is grown on the silicon nitride film 204 to a thickness of 1000 nm by low-pressure CVD. At this time, the TEOS film 205 is also formed on the back of the semiconductor substrate 200. A resist pattern (not shown) is then formed using a mask 206 for photolithography, and using the resist pattern as a mask, the TEOS film 205 is formed into a predetermined shape by dry etching, for example. The resist pattern is then peeled off.

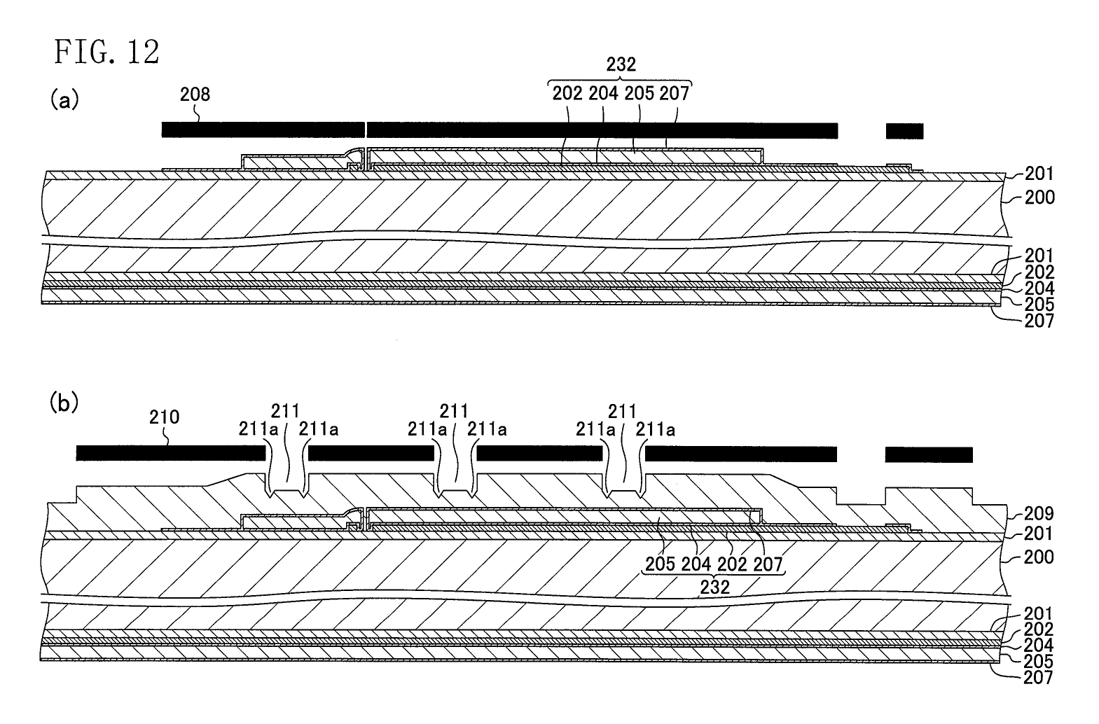

As shown in FIG. 12(a), the silicon nitride film (second silicon nitride film) 207, for example, is then grown on the TEOS film 205 to a thickness of 100 nm as an insulating film. At this time, the silicon nitride film 207 is also formed on the back of the semiconductor substrate 200. A resist pattern (not shown) is then formed using a mask 208 for photolithography, and using the resist pattern as a mask, the silicon nitride film 207 is formed into a predetermined shape by dry etching, for example. In this way, the second multilayer film 232 made of the polysilicon film 202, the silicon nitride film 204, the silicon oxide film 205, and the silicon nitride film 207 is formed. Note that at this etching, a portion of the silicon nitride film 207 in a region for formation of a pad for the second electrode is removed. The resist pattern is then peeled off.

As shown in FIG. 12(b), an atmospheric-pressure CVD oxide film, for example, the BPSG film (third silicon oxide film) 209, is grown on the silicon nitride film 207 to a thickness of 3000 nm. In a later process step, part of the BPSG film 209 is etched away to form the air gap. That is, the BPSG film 209 serves as a sacrificial layer. A resist pattern (not shown) is then formed using a mask 210 for photolithography, and using the resist pattern as a mask, the BPSG film 209 is dry-etched, for example, to form pits 211 for stopper formation. The depth of the pits 211 is 1500 nm, for example. At this time, a portion of the BPSG film 209 in the second electrode pad formation region is removed by a predetermined thickness. The resist pattern is then peeled off.

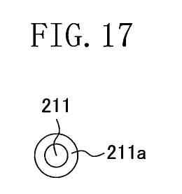

In this embodiment, during the formation of each pit 211, the periphery of the bottom of the pit 211 is further etched by optimizing the dry etching conditions to form a sub-trench 211 a in the pit 211 simultaneously with the formation of the pit 211. The depth of the sub-trench 211a is in the range of 10% or more to 20% or less of the depth of the pit 211 (i.e., in the range of 150 nm or more to 300 nm or less). The shape of the pit 211 in plan is shown in FIG. 17. As shown in FIG. 17, a roughly circular low protrusion of the BPSG film 209 exists in the center of the pit 211, and the sub-trench 211a is formed by further etching a portion of the BPSG film 209 surrounding the protrusion in a roughly ring shape.

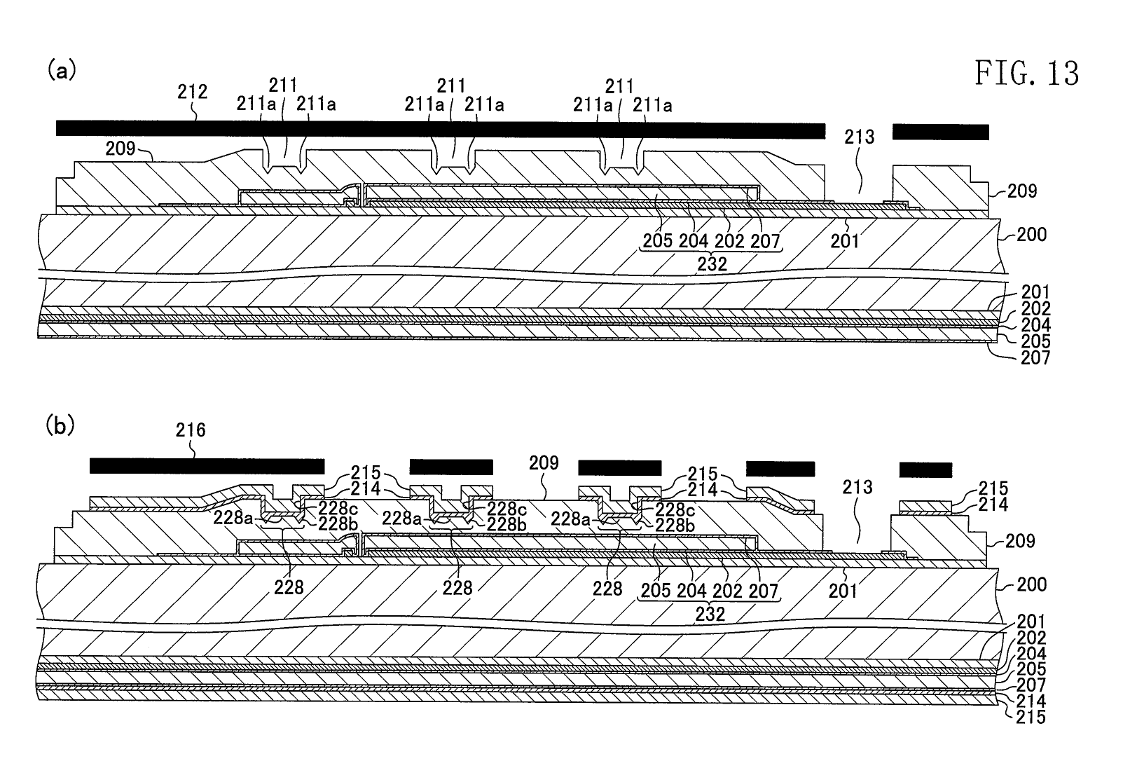

As shown in FIG. 13(a), a resist pattern (not shown) is formed using a mask 212 for photolithography, and using the resist pattern as a mask, the BPSG film 209 is dry-etched, for example, to form the second electrode pad opening 213 reaching the polysilicon film 202 that is to be the second electrode (vibrating electrode). The resist pattern is then peeled off.

As shown in FIG. 13(b), as an insulating film, the silicon nitride film (third silicon nitride film) 214, for example, is formed on the entire surface of the BPSG film 209 including the insides of the pits 211 and the inside of the second electrode pad opening 213 to a thickness of 100 nm. Subsequently, the p-type polysilicon film (second conductive polysilicon film) 215 that is to be the first electrode (fixed electrode) is grown on the silicon nitride film 214 to a thickness of 1000 nm by low-pressure CVD. The polysilicon film 215 is doped with phosphorus in a concentration of 1×10²⁰ to 2×10²⁰ atoms/cm³, for example. At this time, the silicon nitride film 214 and the polysilicon film 215 are also formed on the back of the semiconductor substrate 200. Thereafter, a resist pattern (not shown) is formed using a mask 216 for photolithography, and the silicon nitride film 214 and the polysilicon film 215 are formed into a predetermined shape by dry etching, for example. In this way, the stoppers 228 according to the present invention shown in FIGS. 10(a) and 10(c) are formed. The resist pattern is then peeled off.

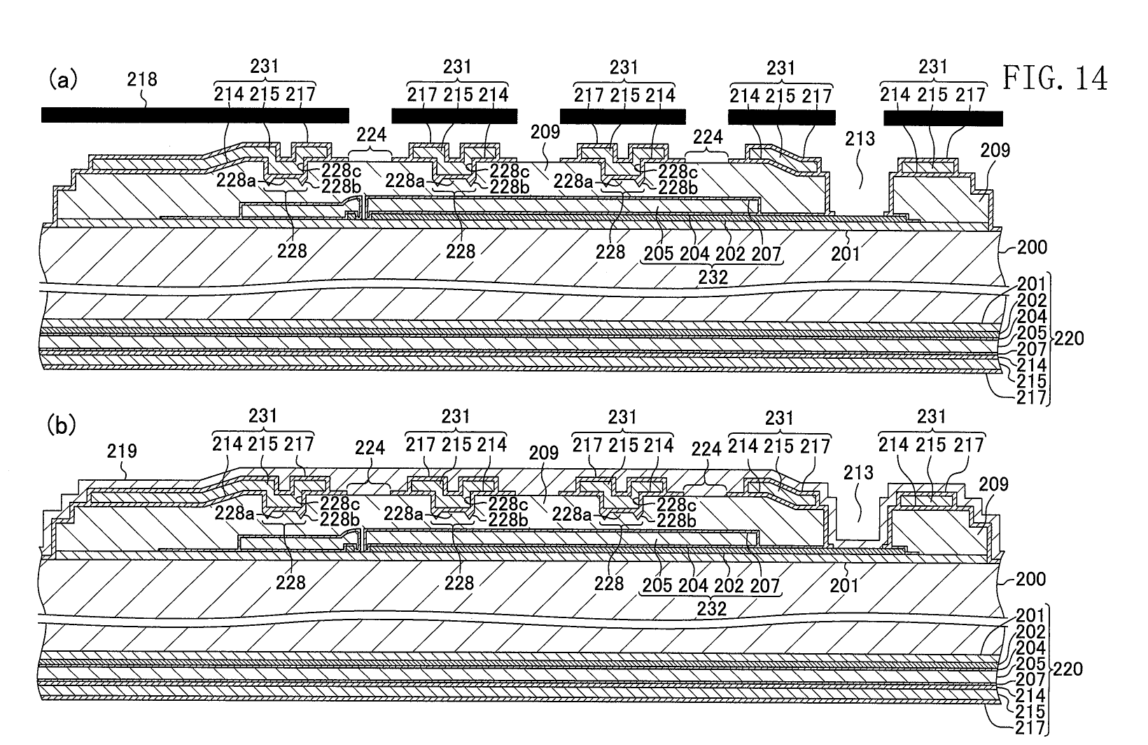

As shown in FIG. 14(a), the silicon nitride film (fourth silicon nitride film) 217 is formed on the entire surface of the BPSG film 209 including the top of the polysilicon film 215 and the inside of the second electrode pad opening 213 to a thickness of 150 nm. At this time, the silicon nitride film 217 is also formed on the back of the semiconductor substrate 200. Hereinafter, the multilayer film on the back of the substrate including the silicon nitride film 217 is called a substrate back multilayer film 220. Thereafter, a resist pattern (not shown) is formed using a mask 218 for photolithography, and using the resist pattern as a mask, the silicon nitride film 217 is formed into a predetermined shape by dry etching, for example. In this way, the first multilayer film 231 made of the silicon nitride film 214, the polysilicon film 215, and the silicon nitride film 217 is formed. The resist pattern is then peeled off.

As shown in FIG. 14(b), a FSG film (fourth silicon oxide film) 219 functioning as a protection film is grown on the entire surface of the BPSG film 209 including the top of the silicon nitride film 217 and the inside of the second electrode pad opening 213 to a thickness of 500 nm.

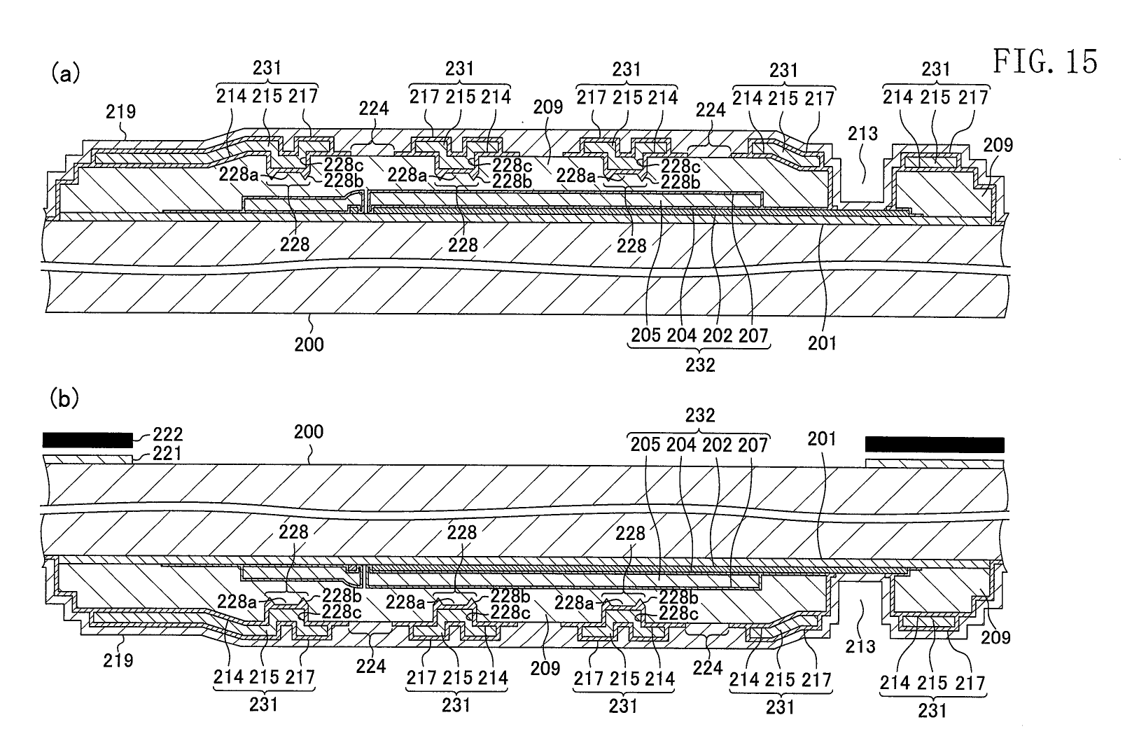

As shown in FIG. 15(a), the substrate back multilayer film 220 is peeled off using back-grinding equipment, for example, to expose the back of the semiconductor substrate 200.

As shown in FIG. 15(b), a silicon oxide film (fifth silicon oxide film) 221 functioning as a protection film is grown on the back of the semiconductor substrate 200 to a thickness of 500 nm. Thereafter, a resist pattern (not shown) is formed using a mask 222 for photolithography, and using the resist pattern as a mask, the silicon oxide film 221 is formed into a predetermined shape by dry etching, for example.

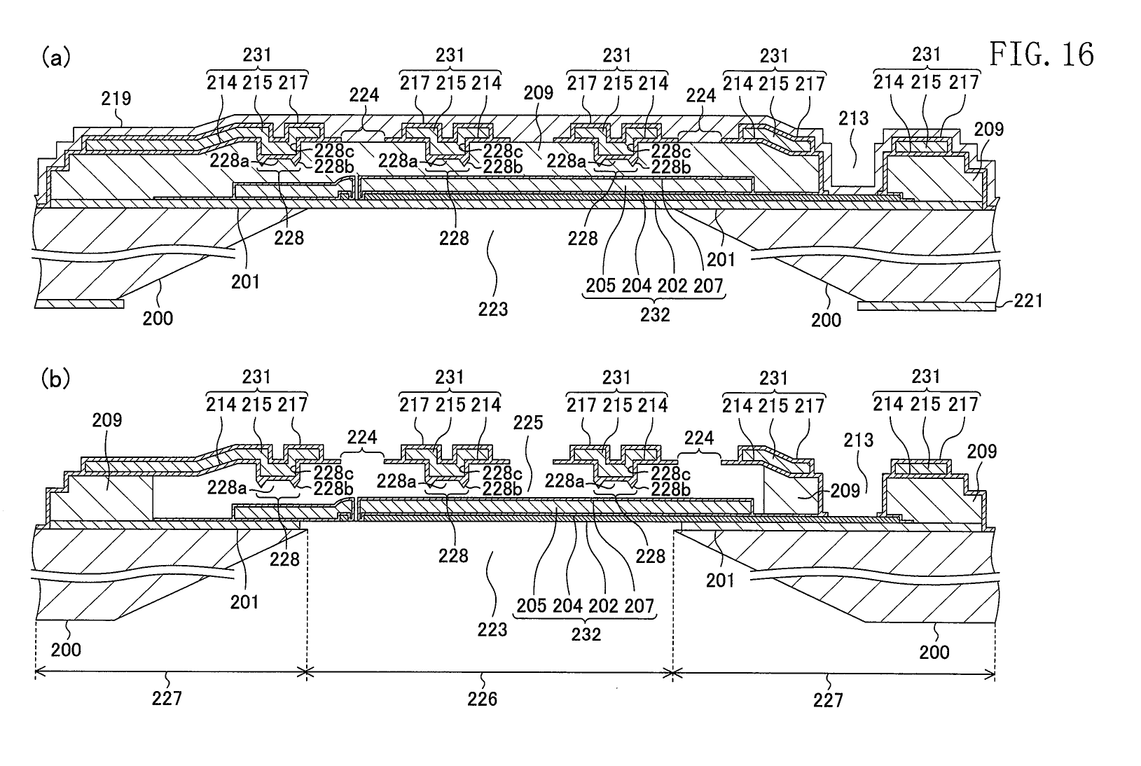

As shown in FIG. 16(a), using the silicon oxide film 221 as the protection film, the semiconductor substrate 200 is subjected to anisotropy etching with a liquid agent such as TMAH, to form a substrate removed portion 223 extending through the center of the semiconductor substrate 200.

As shown in FIG. 16(b), the semiconductor substrate 200 (chip) with the multilayer films 231 and 232 formed thereon is immersed in an undiluted HF solution, to remove the FSG film 219 functioning as the protection film, the silicon oxide film 221, the BPSG film 209 (predetermined portion), and the protection oxide film 201 (predetermined portion) by wet etching. In this way, the air gap 225 communicating with the acoustic holes 224 is formed between the first multilayer film 231 and the second multilayer film 232.

Finally, charge is applied to the silicon oxide film 205 as the electret film covered with the silicon nitride films 204 and 207 to turn the silicon oxide film 205 into an electret, to thereby complete the condenser microphone.

### Embodiment 3

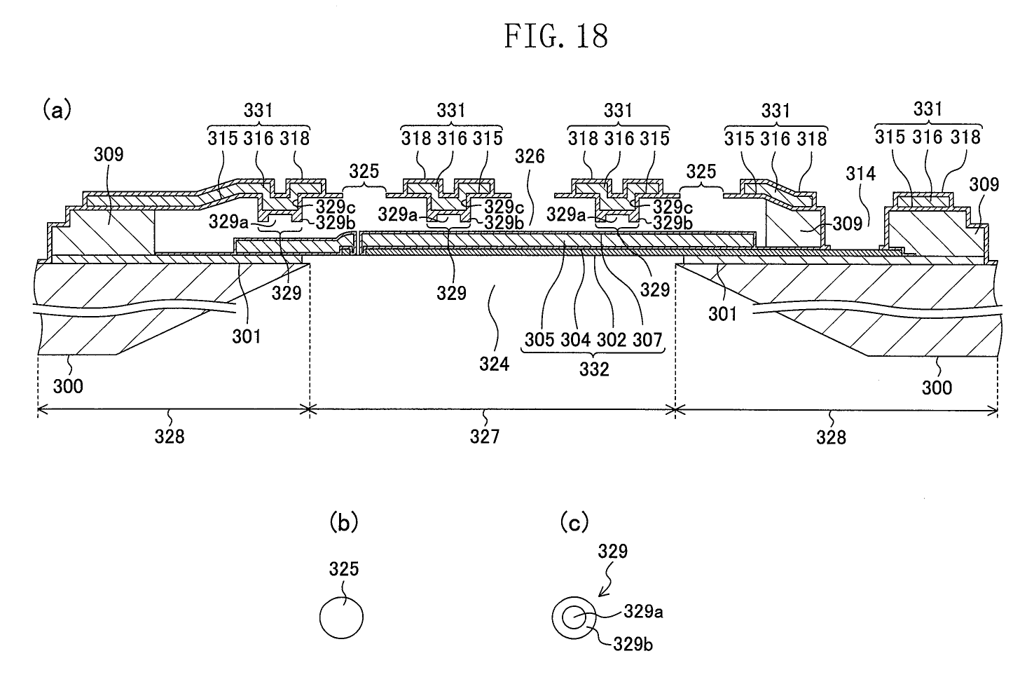

Hereinafter, a condenser microphone of Embodiment 3 of the present invention will be described with reference to FIGS. 18(a) to 18(c).

As shown in the cross-sectional view of FIG. 18(a), the condenser microphone of Embodiment 3 includes a semiconductor substrate 300 having a substrate removed portion 324 in the center, or to state differently, a semiconductor substrate 300 having a membrane region 327 and a peripheral region 328 (part of the region outside the membrane region 327). As the semiconductor substrate 300, used is a silicon single crystal having a (100) principal plane and a specific resistance of 10 to 15 Ω·cm, for example. A protection oxide film (first silicon oxide film) 301 is formed on the peripheral region 328 of the semiconductor substrate 300. A multilayer film (second multilayer film) 332 made of a polysilicon film (first conductive polysilicon film) 302, a silicon nitride film (first silicon nitride film) 304, a silicon oxide film (second silicon oxide film) 305, and a silicon nitride film (second silicon nitride film) 307 is formed on the membrane region 327 of the semiconductor substrate 300 and the protection oxide film 301. The polysilicon film 302, serving as a second electrode (vibrating electrode), is formed under the silicon nitride film 304. The silicon nitride film 304 is formed to cover the bottom of the silicon oxide film 305, while the silicon nitride film 307 is formed to cover the top and sides of the silicon oxide film 305. The silicon oxide film 305, which stores charge, functions as an electret film.

Also, as shown in FIG. 18(a), a multilayer film (first multilayer film) 331 made of a silicon nitride film (third silicon nitride film) 315, a polysilicon film (second conductive polysilicon film) 316, and a silicon nitride film (fourth silicon nitride film) 318 is formed on the second multilayer film 332. Acoustic holes 325 as through holes are formed through the first multilayer film 331. The shape of each acoustic hole 325 in plan is shown in FIG. 18(b). The polysilicon film 316 serves as a first electrode (fixed electrode). The silicon nitride film 315 is formed to cover the bottom of the polysilicon film 316, while the silicon nitride film 318 is formed to cover the top and sides of the polysilicon film 316. Between the first multilayer film 331 and the second multilayer film 332, an air gap 326 exists, which is formed by etching away part of an atmospheric-pressure CVD oxide film, for example, a BPSG film (third silicon oxide film) 309. The remainder of the BPSG film 309 left unetched serves as a support layer for supporting the first multilayer film 331. A second electrode pad opening 314 is formed through the BPSG film 309 to reach the polysilicon film 302 that is to be the second electrode (vibrating electrode).

A feature of Embodiment 3 is that the first multilayer film 331 has a plurality of stoppers 329 protruding toward the second multilayer film 332 and a recess 329a communicating with the air gap 326 is formed in the center of each stopper 329. The stoppers 329 have a height of about 1500 nm, for example, and a diameter of about 4 μm, for example. The diameter of the recess 329a is about 3 μm, for example, and the density of the stoppers 329 is one/35000 μm² to one/180000 μm², for example. Specifically, each stopper 329 is made of a portion of the silicon nitride film 315 (part of the first multilayer film 331) formed to protrude toward the second multilayer film 332 and the polysilicon film 316 filling a groove 329c formed from the protrusion. Also, a rim 329b of each stopper 329 further protrudes toward the second multilayer film 332 with respect to the other portion by about 150 to 300 nm, to form the recess 329a surrounded by the rim 329b. The shape of the stopper 329 in plan is shown in FIG. 18(c).

Unlike Embodiment 1, the polysilicon film 316 is not embedded in a portion of the rim 329b of each stopper 329 adjacent to the recess 329a.

Also, in the stoppers 329 in Embodiment 3, unlike those in Embodiment 1, the bottom surface of the recess 329a of each stopper 329 is not flush with the surface of the first multilayer film 331 (specifically, the silicon nitride film 315) facing the second multilayer film 332 other than the portions of the stoppers 329. In other words, while the recess 128a of each stopper 128 is deep enough to reach the level of the surface of the first multilayer film 131 facing the second multilayer film 132 other than the portions of the stoppers 128 in Embodiment 1 as shown in FIG. 1(a), the recess 329a of each stopper 329 is not deep enough to reach the level of the surface of the first multilayer film 331 facing the second multilayer film 332 other than the portions of the stoppers 329 in Embodiment 3 as shown in FIG. 18(a). To state differently, the bottom of the recess 329a is located closer to the second multilayer film 332 than the surface of the first multilayer film 331 facing the second multilayer film 332 other than the portions of the stoppers 329 is. Hence, in the stoppers 329 in Embodiment 3, the polysilicon film 316 is embedded in a portion of each stopper 329 ranging from the surface of the first multilayer film 331 facing the second multilayer film 332 other than the portions of the stoppers 329 to the bottom of the recess 329a.

In the condenser microphone of Embodiment 3, in which the recess 329a communicating with the air gap 326 is formed in the center of each stopper 329 of the first multilayer film 331, the contact area between the stopper 329 and the second multilayer film 332 can be reduced even when the first multilayer film 331 and the second multilayer film 332 come close to each other. Hence, even if a foreign matter including water enters the air gap 326, the surface tension of such a foreign matter will be small, and thus the sticking phenomenon can be reliably suppressed. Accordingly, a high-performance condenser microphone good in sticking resistance can be implemented without the necessity of changing the stopper size even when the number of stoppers is increased.

Also, in the condenser microphone of Embodiment 3, the inventive stopper structure described above can solve a problem that the first multilayer film 331 and the second multilayer film 332 may stick to each other due to the surface tension of an etchant, a cleaning solution, or the like. That is, a condenser microphone capable of exerting strong sticking resistance even during fabrication can be implemented.

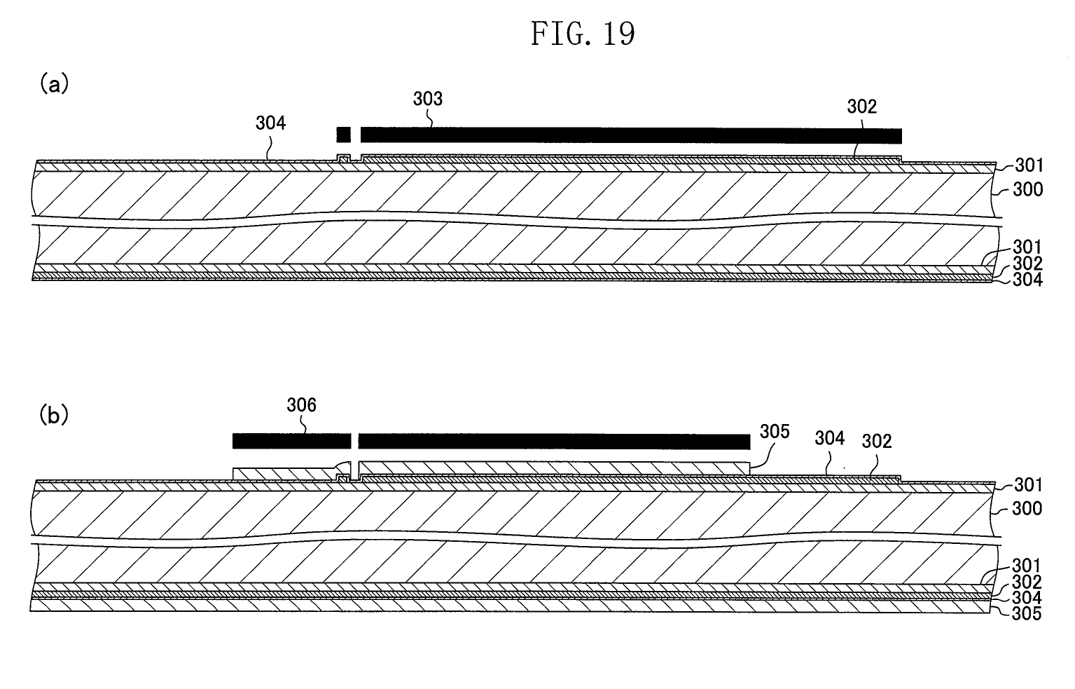

Next, a fabrication method for the condenser microphone of Embodiment 3 of the present invention will be described with reference to the cross-sectional views of FIGS. 19(a), 19(b), 20(a), 20(b), 21(a), 21(b), 22(a), 22(b), 23(a), 23(b), 24(a), 24(b), and 25 showing process steps of the fabrication method. Note that description of resist film removal steps is omitted because the steps follow normal processing. Also, it is needless to mention that the numeric values of the thicknesses and the like, the materials of the film species and the like, the methods such as the etching method, and the like in the following description are all presented for mere illustration.

First, as shown in FIG. 19(a), the protection oxide film (first silicon oxide film) 301 having a thickness of 1000 nm, for example, is formed on the p-type semiconductor substrate 300 made of a silicon single crystal having a (100) principal plane and a specific resistance of 10 to 15 Ω·cm. Thereafter, the p-type polysilicon film (first conductive polysilicon film) 302 that is to be the second electrode (vibrating electrode) is grown on the protection oxide film 301 to a thickness of 300 nm by low-pressure CVD. The polysilicon film 302 is doped with phosphorus in a concentration of 2×10²⁰ to 3×10²⁰ atoms/cm³, for example. A resist pattern (not shown) is then formed using a mask 303 for photolithography, and using the resist pattern as a mask, the polysilicon film 302 is formed into a predetermined shape by dry etching, for example. The resist pattern is then peeled off. The silicon nitride film (first silicon nitride film) 304, for example, is then grown on the protection oxide film 301 and the polysilicon film 302 to a thickness of 100 nm as an insulating film. Note that at this time, the protection oxide film 301, the polysilicon film 302, and the silicon nitride film 304 are also formed on the back of the semiconductor substrate 300.

As shown in FIG. 19(b), the TEOS (second silicon oxide film) 305 is grown on the silicon nitride film 304 to a thickness of 1000 nm by low-pressure CVD. At this time, the TEOS film 305 is also formed on the back of the semiconductor substrate 300. A resist pattern (not shown) is then formed using a mask 306 for photolithography, and using the resist pattern as a mask, the TEOS film 305 is formed into a predetermined shape by dry etching, for example. The resist pattern is then peeled off.

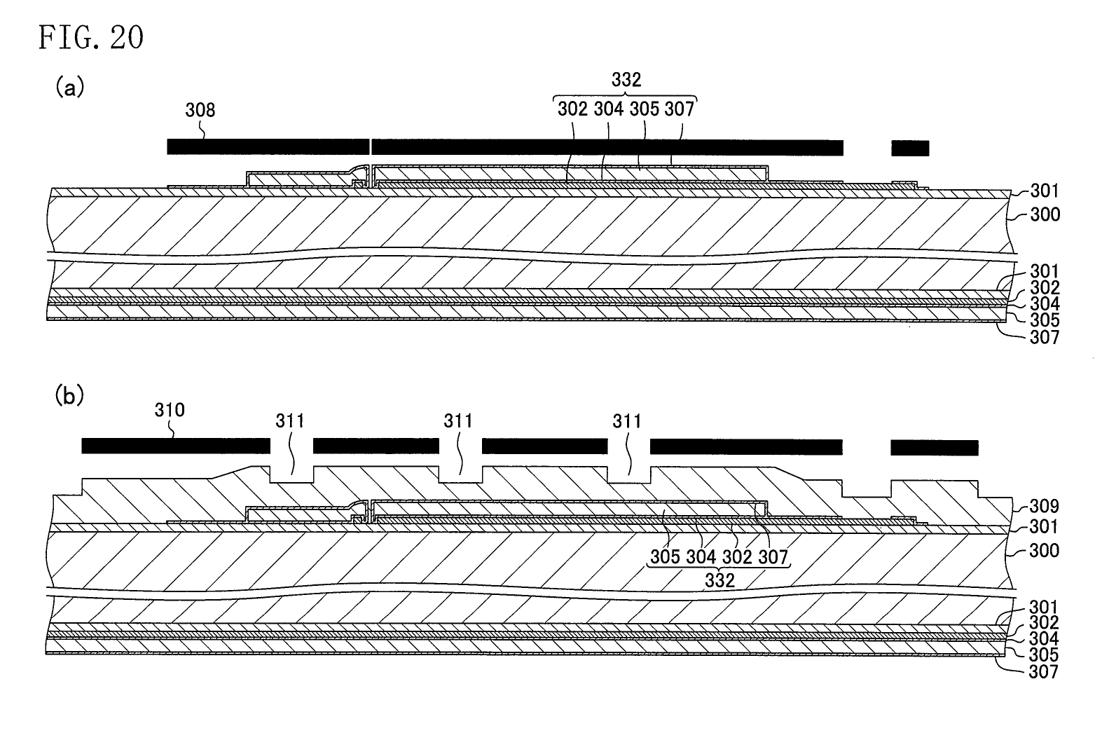

As shown in FIG. 20(a), the silicon nitride film (second silicon nitride film) 307, for example, is then grown on the TEOS film 305 to a thickness of 100 nm as an insulating film. At this time, the silicon nitride film 307 is also formed on the back of the semiconductor substrate 300. A resist pattern (not shown) is then formed using a mask 308 for photolithography, and using the resist pattern as a mask, the silicon nitride film 307 is formed into a predetermined shape by dry etching, for example. In this way, the second multilayer film 332 made of the polysilicon film 302, the silicon nitride film 304, the silicon oxide film 305, and the silicon nitride film 307 is formed. Note that at this etching, a portion of the silicon nitride film 307 in a region for formation of a pad for the second electrode is removed. The resist pattern is then peeled off.

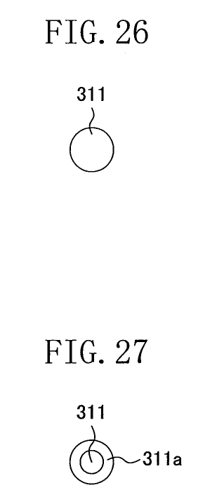

As shown in FIG. 20(b), an atmospheric-pressure CVD oxide film, for example, the BPSG film (third silicon oxide film) 309, is grown on the silicon nitride film 307 to a thickness of 3000 nm. In a later process step, part of the BPSG film 309 is etched away to form the air gap. That is, the BPSG film 309 serves as a sacrificial layer. A resist pattern (not shown) is then formed using a mask 310 for photolithography, and using the resist pattern as a mask, the BPSG film 309 is dry-etched, for example, to form pits 311 for stopper formation. The shape of each pit 311 in plan is shown in FIG. 26. The depth of the pits 311 is 1500 nm, for example. At this time, a portion of the BPSG film 309 in the second electrode pad formation region is removed by a predetermined thickness. The resist pattern is then peeled off.

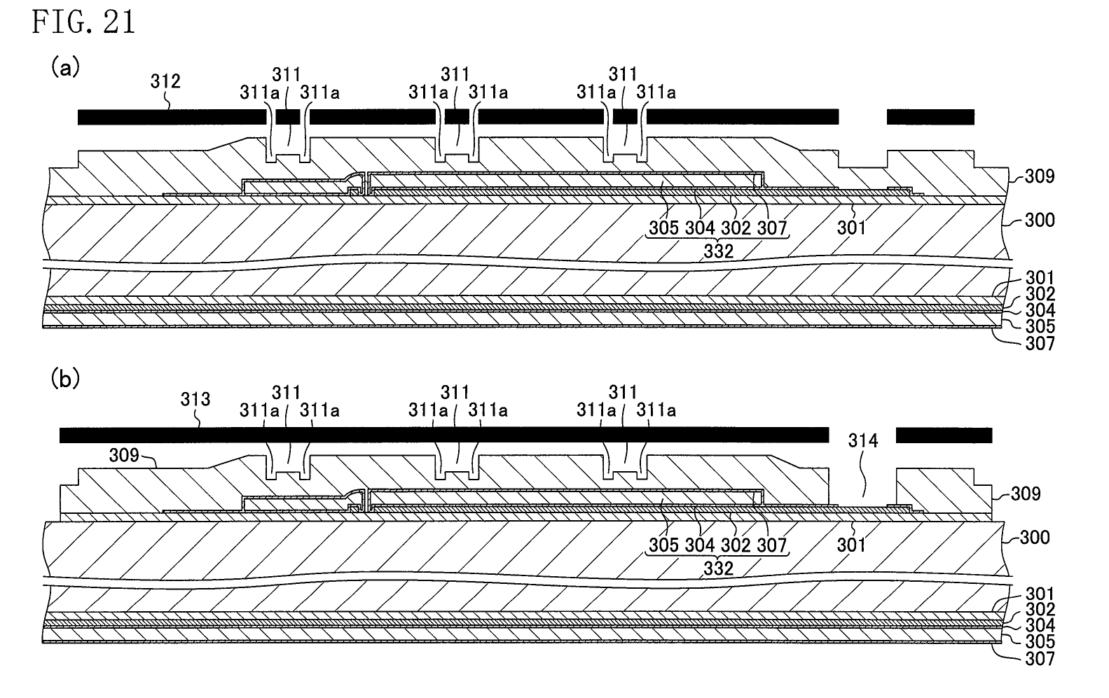

As shown in FIG. 21(a), a resist pattern (not shown) is formed using a mask 312 for photolithography, and using the resist pattern as a mask, the BPSG film 309 is dry-etched, for example, to further etch the periphery of the bottom of each pit 311 forming a sub-trench 311a. The resist pattern is then peeled off. The depth of the sub-trench 311a is in the range of 10% or more to 20% or less of the depth of the pit 311 (i.e., in the range of 150 nm or more to 300 nm or less). The shape of the pit 311 having the sub-trench 311a in plan is shown in FIG. 27. As shown in FIG. 27, a roughly circular low protrusion of the BPSG film 309 exists in the center of the pit 311, and the sub-trench 311a is formed by further etching a portion of the BPSG film 309 surrounding the protrusion in a roughly ring shape.

As shown in FIG. 21 (b), a resist pattern (not shown) is formed using a mask 313 for photolithography, and using the resist pattern as a mask, the BPSG film 309 is dry-etched, for example, to form the second electrode pad opening 314 reaching the polysilicon film 302 that is to be the second electrode (vibrating electrode). The resist pattern is then peeled off.

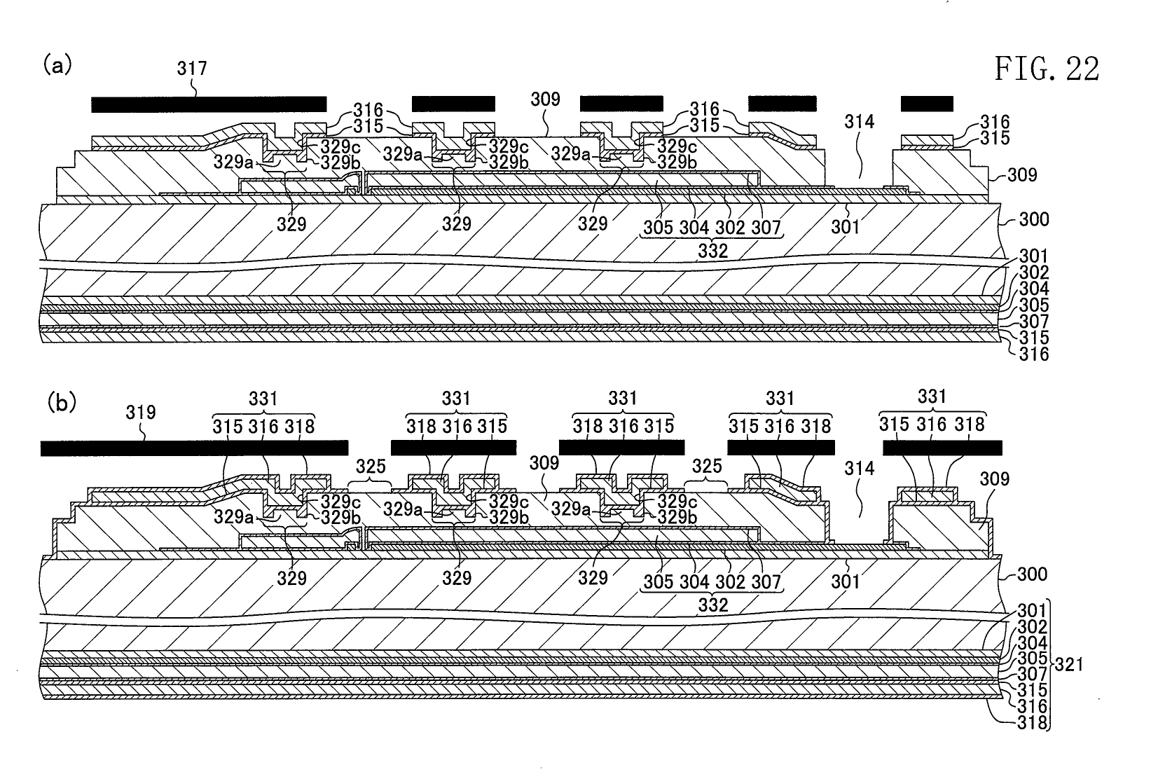

As shown in FIG. 22(a), as an insulating film, the silicon nitride film (third silicon nitride film) 315, for example, is formed on the entire surface of the BPSG film 309 including the insides of the pits 311 and the inside of the second electrode pad opening 314 to a thickness of 100 nm. Subsequently, the p-type polysilicon film (second conductive polysilicon film) 316 that is to be the first electrode (fixed electrode) is grown on the silicon nitride film 315 to a thickness of 1000 nm by low-pressure CVD. The polysilicon film 316 is doped with phosphorus in a concentration of 1×10²⁰ to 2×10²⁰ atoms/cm³, for example. At this time, the silicon nitride film 315 and the polysilicon film 316 are also formed on the back of the semiconductor substrate 300. Thereafter, a resist pattern (not shown) is formed using a mask 317 for photolithography, and the silicon nitride film 315 and the polysilicon film 316 are formed into a predetermined shape by dry etching, for example. In this way, the stoppers 329 according to the present invention shown in FIGS. 18(a) and 18(c) are formed. The resist pattern is then peeled off.

As shown in FIG. 22(b), the silicon nitride film (fourth silicon nitride film) 318 is formed on the entire surface of the BPSG film 309 including the top of the polysilicon film 316 and the inside of the second electrode pad opening 314 to a thickness of 150 nm. At this time, the silicon nitride film 318 is also formed on the back of the semiconductor substrate 300. Hereinafter, the multilayer film on the back of the substrate including the silicon nitride film 318 is called a substrate back multilayer film 321. Thereafter, a resist pattern (not shown) is formed using a mask 319 for photolithography, and using the resist pattern as a mask, the silicon nitride film 318 is formed into a predetermined shape by dry etching, for example. In this way, the first multilayer film 331 made of the silicon nitride film 315, the polysilicon film 316, and the silicon nitride film 318 is formed. The resist pattern is then peeled off.

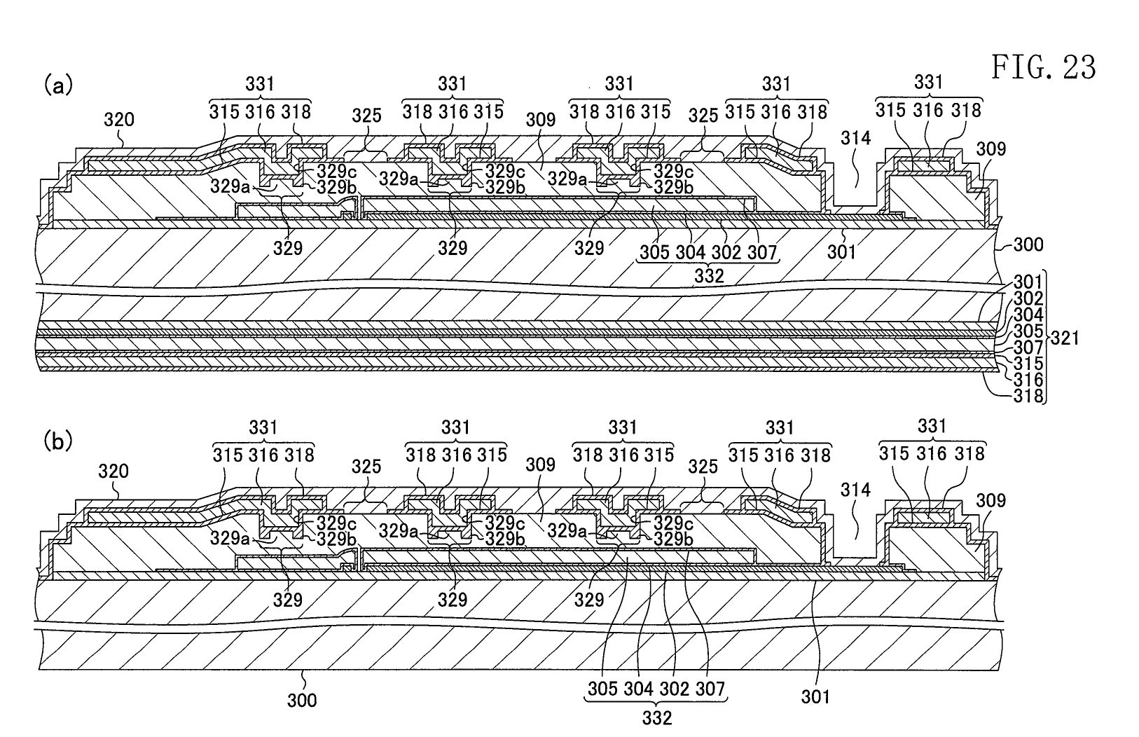

As shown in FIG. 23(a), a FSG film (fourth silicon oxide film) 320 functioning as a protection film is grown on the entire surface of the BPSG film 309 including the top of the silicon nitride film 318 and the inside of the second electrode pad opening 314 to a thickness of 500 nm.

As shown in FIG. 23(b), the substrate back multilayer film 321 is peeled off using back-grinding equipment, for example, to expose the back of the semiconductor substrate 300.

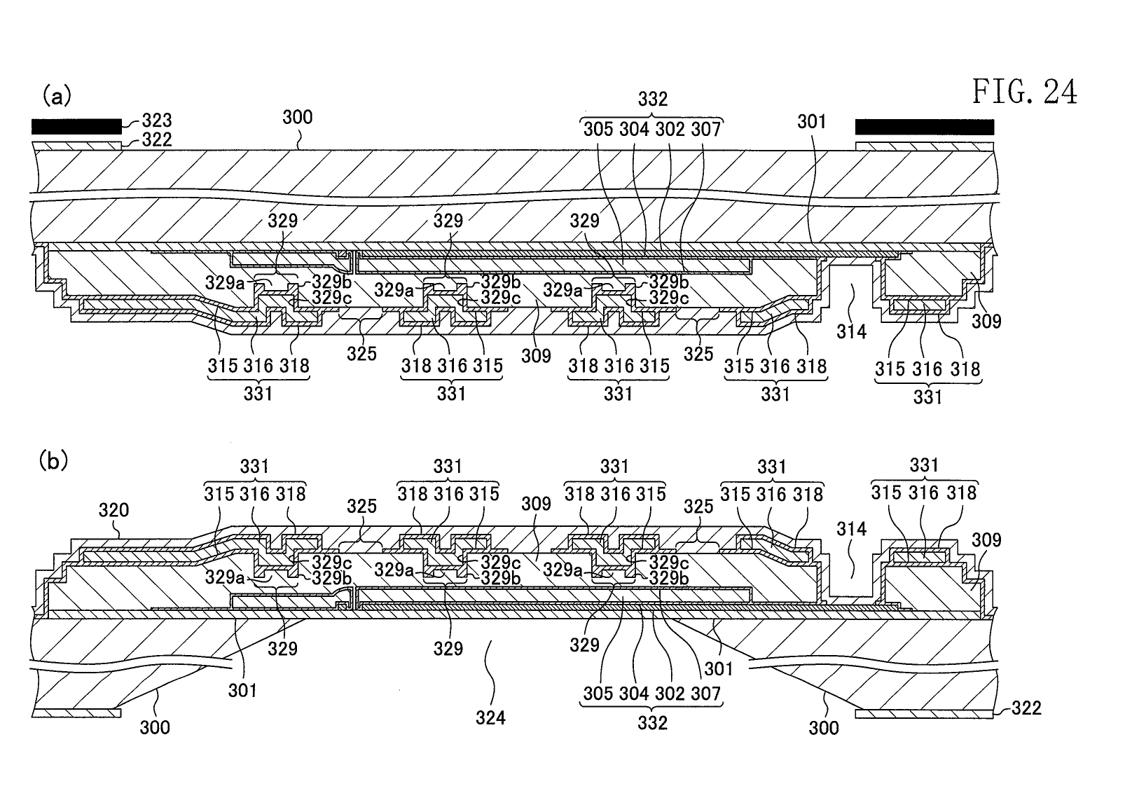

As shown in FIG. 24(a), a silicon oxide film (fifth silicon oxide film) 322 functioning as a protection film is grown on the back of the semiconductor substrate 300 to a thickness of 500 nm. Thereafter, a resist pattern (not shown) is formed using a mask 323 for photolithography, and using the resist pattern as a mask, the silicon oxide film 322 is formed into a predetermined shape by dry etching, for example.

As shown in FIG. 24(b), using the silicon oxide film 322 as the protection film, the semiconductor substrate 300 is subjected to anisotropy etching with a liquid agent such as TMAH, to form a substrate removed portion 324 extending through the center of the semiconductor substrate 300.

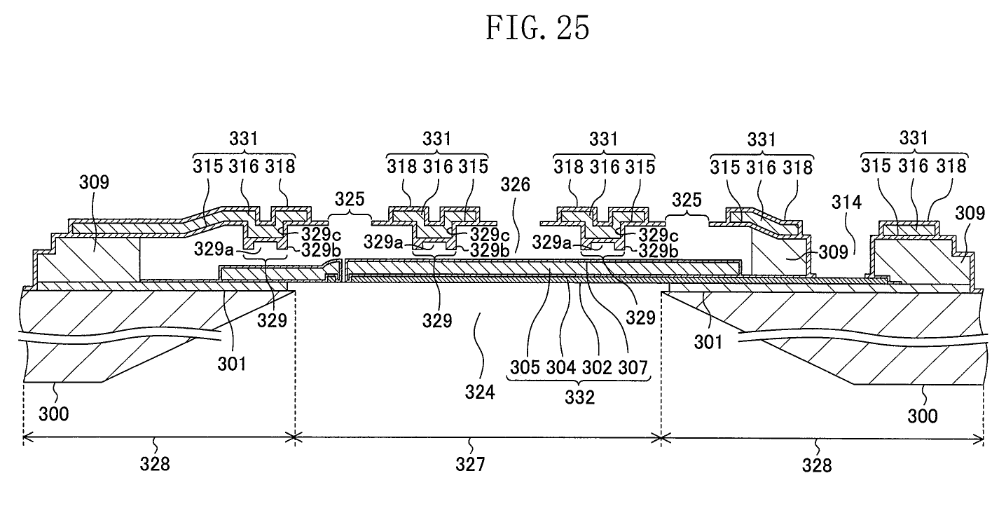

As shown in FIG. 25, the semiconductor substrate 300 (chip) with the multilayer films 331 and 332 formed thereon is immersed in an undiluted HF solution, to remove the FSG film 320 functioning as the protection film, the silicon oxide film 322, the BPSG film 309 (predetermined portion), and the protection oxide film 301 (predetermined portion) by wet etching. In this way, the air gap 326 communicating with the acoustic holes 325 is formed between the first multilayer film 331 and the second multilayer film 332.

Finally, charge is applied to the silicon oxide film 305 as the electret film covered with the silicon nitride films 304 and 307 to turn the silicon oxide film 305 into an electret, to thereby complete the condenser microphone.

In Embodiments 1 to 3, the invention was applied to the electret-type condenser microphones. However, similar effects will also be obtained by applying the invention to electret-free capacitive condenser microphones.

In Embodiments 1 to 3, the p-type semiconductor substrate was used. Instead, an n-type semiconductor substrate may be used. Also, the p-type polysilicon film was used as each electrode film. Alternatively, a non-doped polysilicon film may be formed and then ions may be implanted in the polysilicon film, to form a p-type polysilicon film. In place of the p-type polysilicon film, an n-type polysilicon film may be used.

In Embodiments 1 to 3, the processes were described in a specific way. Alternatively, it is needless to mention that an arbitrary process can be selected from a group of mutually exchangeable processes, such as a group of thermal oxidation and CVD in the case of forming an oxide film and a group of dry etching and wet etching in the case of etching.

In Embodiments 1 to 3, the shape of the stoppers 128, 228 and 329 in plan was circular. The shape is not limited to this, but similar effects will also be obtained when the stoppers are in the shape in plan of a polygon such as a triangle, a rectangle, a hexagon, and an octagon.

In the fabrication method for the condenser microphone of Embodiment 3, a total of nine masks for photolithography were used. In the fabrication method for the condenser microphone of Embodiment 2, however, the condenser microphone can be completed with use of only eight masks for photolithography because the sub-trenches 211a are formed simultaneously with the pits 211 by optimizing the dry etching conditions. In other words, the fabrication method for the condenser microphone of Embodiment 2 provides the effect of reducing the number of steps compared with the fabrication method for the condenser microphone of Embodiment 3.

In Embodiments 1 to 3, the capacitive condenser microphones were taken to describe the invention. The present invention is not limited to these embodiments, but a variety of modifications and applications can be made as long as the effects of the present invention are exerted. Specifically, similar effects to those obtained in the embodiments described above can be obtained when the present invention is applied to other MEMS devices having the same basic configuration as the condenser microphones of the embodiments, such as pressure sensors, for example. Note that in the present application, the MEMS technology refers to a technology in which a substrate (wafer) on which a number of chips have been fabricated simultaneously using a fabrication process technique for complementary metal-oxide semiconductors (CMOS) and the like, for example, is cut into individual chips, to obtain devices such as capacitive condenser microphones and pressure sensors. Devices fabricated using such MEMS technology are called MEMS devices. It is needless to mention that the present invention may also be applied to various devices other than MEMS devices such as capacitive condenser microphones and pressure sensors without departing from the spirit of the present invention.

As described above, by applying the present invention to MEMS devices, high-performance MEMS devices excellent in sticking resistance performance, moisture resistance, and condensation resistance can be implemented. The present invention is therefore very useful.

What is claimed is:

1. A condenser microphone comprising:
a first film having a first electrode film;
a second film having a second electrode film; and
an air gap formed between the first film and the second film,
wherein the first film has a stopper protruding toward the second film, and
a recess communicating with the air gap is provided in the center of the stopper.

2. The condenser microphone of claim 1, wherein the first electrode film is also formed inside the stopper.

3. The condenser microphone of claim 1, wherein the first electrode film is also formed in a portion of a rim of the stopper adjacent to the recess.

4. The condenser microphone of claim 1, wherein the bottom surface of the recess is flush with a surface of the first film facing the second film other than a portion of the stopper.

5. The condenser microphone of claim 1, wherein the bottom surface of the recess is not flush with a surface of the first film facing the second film other than a portion of the stopper.

6. The condenser microphone of claim 1, wherein the first film further has a silicon nitride film covering a surface of the first electrode film facing the second film.

7. The condenser microphone of claim 1, wherein the second film further has a silicon oxide film and a silicon nitride film covering the silicon oxide film.

8. The condenser microphone of claim 1, wherein the first electrode film is made of polysilicon.

9. The condenser microphone of claim 1, wherein the second electrode film is made of polysilicon.

10. A MEMS device comprising:
a first film having a first electrode film;
a second film having a second electrode film; and
an air gap formed between the first film and the second film,
wherein the first film has a stopper protruding toward the second film, and
a recess communicating with the air gap is provided in the center of the stopper.
